(19) United States
(12) Patent Application Publication
(10) Pub. No.: US 2026/0068328 A1
(43) Pub. Date: Mar. 5, 2026

(54) INTEGRATED CIRCUIT DEVICE AND MANUFACTURING METHOD THEREOF

(71) Applicants: TAIWAN SEMICONDUCTOR MANUFACTURING COMPANY, LTD., Hsinchu (TW); TSMC Nanjing Company Limited, Nanjing, Jiangsu Province (CN); TSMC China Company Limited, Shanghai (CN)

(72) Inventors: CunCun CHEN, Shanghai City (CN); XinYong WANG, Shanghai City (CN); Liu HAN, Nanjing City (CN); Huan-Neng CHEN, Taichung City (TW); JunFang TU, Nanjing City (CN)

(73) Assignees: TAIWAN SEMICONDUCTOR MANUFACTURING COMPANY, LTD., Hsinchu (TW); TSMC Nanjing Company Limited, Nanjing, Jiangsu Province (CN); TSMC China Company Limited, Shanghai (CN)

(21) Appl. No.: 18/896,390

(22) Filed: Sep. 25, 2024

(30) Foreign Application Priority Data
Sep. 4, 2024 (CN) 202422172042.5

(51) Int. Cl. H01L 27/02; H01L 23/528; H01L 27/092

(52) U.S. Cl. CPC H10D 89/811; H10D 84/85

(57) ABSTRACT

An integrated circuit device includes a semiconductor substrate, a plurality of multi-bit cells over the semiconductor substrate, a first pad, and a second pad. Each of the multi-bit cells includes first and second bits. The first bit includes a first electrostatic discharge (ESD) protection circuit and a first strap region in the semiconductor substrate. The second bit includes a second ESD protection circuit and a second strap region in the semiconductor substrate. The first strap region of the first bit is symmetric to the second strap region of the second bit with respect to a border between the first bit and the second bit in a top view, and the first p-type strap region of the first bit and the second strap region of the second bit have a first conductivity type. The first and second pads are respectively connected to the first and second ESD protection circuits.

### PRIORITY CLAIM AND CROSS-REFERENCE

This application claims priority to China Application Serial Number 202422172042.5, filed Sep. 4, 2024, which is herein incorporated by reference.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of a stacked integrated circuit (IC) device in accordance with some embodiments of the present disclosure.

FIG. 1B illustrates a schematic block diagram of the stacked IC device of FIG. 1A.

FIG. 1C is a cross-sectional view of the stacked IC device of FIG. 1A.

FIG. 2A illustrates a schematic block diagram showing operations of an ESD protection circuit.

FIG. 2B illustrates a circuit diagram of the ESD protection circuit in FIG. 2A.

FIG. 2C is a cross-sectional view of a portion of the ESD protection circuit of FIG. 2B.

FIG. 2D is a cross-sectional view of a portion of the ESD protection circuit of FIG. 2B.

FIG. 3A is a schematic view of an IC device in accordance with some embodiments of the present disclosure.

FIG. 3B illustrates a schematic arrangement of a plurality of bits in the IC device of FIG. 3A.

FIG. 3C shows a layout of the IC device of FIG. 3A.

FIG. 3D is an enlarged view of an n-type strap region in an ESD protection circuit in FIG. 3C.

FIG. 3E is an enlarged view of a p-type strap region in an ESD protection circuit in FIG. 3C.

FIG. 3F is an enlarged view of an n-type device in an ESD protection circuit in FIG. 3C.

FIG. 3G is an enlarged view of a p-type device in an ESD protection circuit in FIG. 3C.

FIG. 4 is a schematic view of an IC device in accordance with some embodiments of the present disclosure.

FIG. 5A is a is a schematic view of an IC device in accordance with some embodiments of the present disclosure.

FIG. 5B illustrates a schematic arrangement of a plurality of bits in the IC device of FIG. 5A.

FIG. 5C shows a layout of the IC device of FIG. 5A.

FIG. 6A is a is a schematic view of an IC device in accordance with some embodiments of the present disclosure.

FIG. 6B illustrates a schematic arrangement of a plurality of bits in the IC device of FIG. 6A.

FIG. 6C shows a layout of the IC device of FIG. 6A.

FIG. 7 illustrates a schematic arrangement of a plurality of bits in an IC device in accordance with some embodiments of the present disclosure.

FIG. 8 illustrates a schematic arrangement of a plurality of bits in an IC device in accordance with some embodiments of the present disclosure.

FIG. 9 illustrates a schematic arrangement of a plurality of bits in an IC device in accordance with some embodiments of the present disclosure.

FIG. 10 illustrates a schematic arrangement of a plurality of bits in an IC device in accordance with some embodiments of the present disclosure.

FIGS. 11A-15B illustrate layouts and cross-sectional views of an integrated circuit structure at intermediate stages of manufacturing process according to some embodiments of the present disclosure.

FIG. 16 is a schematic diagram of an electronic design automation (EDA) system in accordance with some embodiments of the present disclosure.

FIG. 17 is a block diagram of an IC manufacturing system and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

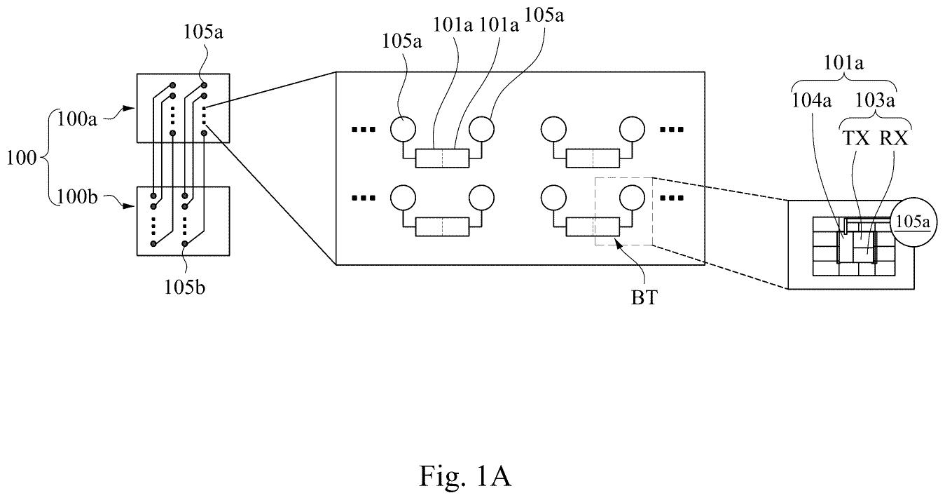

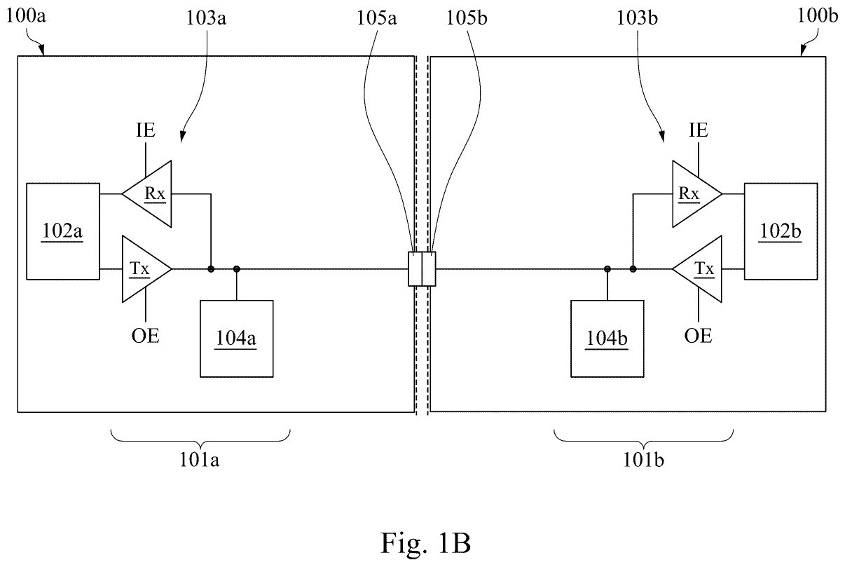

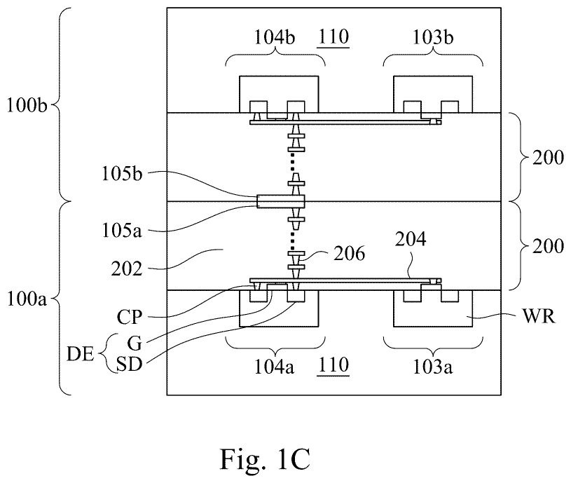

FIG. 1A is a schematic view of a stacked integrated circuit (IC) device in accordance with some embodiments of the present disclosure. The IC device 100 comprises a first die 100a and a second die 100b electrically and/or physically coupled to each other. In some embodiments, the first die 100a and the second die 100b are stacked over each other, and are physically bonded and electrically coupled to each other in a 3D IC through pads 105a and 105b thereof. In some embodiments, the first die 100a and the second die 100b are arranged side-by-side on and physically bonded to a further substrate or die (not shown), and are electrically coupled to each other through the further substrate or die. In some embodiments, the IC device 100 comprises more than two dies electrically and/or physically coupled to each other. In some embodiments, the IC device 100 has one die, e.g., the first die 100a, whereas the other die, e.g., the second die 100b, is omitted. In the example configuration in FIG. 1A, the second die 100b is configured similarly to the first die 100a. The first die 100a is described in detail herein, and a detailed description of the second die 100b is omitted.

FIG. 1B illustrates a schematic block diagram of the stacked IC device of FIG. 1A. Reference is made to FIG. 1A and FIG. 1B. The first die 100a can include one or more logic circuits 102a and one or more input/output (I/O) circuits 101a electrically coupled between the one or more logic circuits 102a and the pads 105a. In FIG. 1B, a representative I/O circuit 101a and a representative logic circuit 102a of the first die 100a are illustrated. In some embodiment, the I/O circuit 101b and the logic circuit 102b of the second die 100b can correspond to the I/O circuit 101a and the logic circuit 102a of the first die 100a. In FIG. 1A, plural bits BT are repeated, and each of the bits BT include a I/O circuit 101a connected to a pad 105a. The adjacent bits BT can be arranged in a manner to save regions for the I/O circuits 101a and satisfying a design rule check (DRC), which are described later with layouts.

In some embodiment, the logic circuit 102a can be configured to perform an intended function, e.g., data processing or data storage, of the IC device 100. Examples of one or more circuits, logics, or cells included in the logic circuit 102a include, but are not limited to, AND, OR, NAND, NOR, XOR, INV, OR-AND-Invert (OAI), MUX, Flip-flop, BUFF, Latch, delay, clock, memory, or the like. The circuits, logics, or cells included in the logic circuit 102a include functional transistors or core transistors which are to be protected from the antenna effect during the manufacture of the IC device 100. Examples of transistors in the logic circuit 102a, as well as in the other circuits described herein, include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

In some embodiment, the I/O circuit 101a can be electrically coupled to the logic circuit 102a, and can be configured as an interface between the logic circuit 102a on the first die 100a and external circuitry outside the first die 100a. In the example configuration in FIG. 1A, the I/O circuit 101a can include the buffer circuit 103a and the ESD protection circuit 104a, in which the buffer circuit 103a may include a receiving circuit RX (also referred to as “input circuit”) and a transferring circuit TX (also referred to as “output circuit”), and all of which are electrically coupled to a pad 105a which can be an I/O pin. In some embodiment, the buffer circuit 103b, the ESD protection circuit 104b, and the pad 105b of the second die 100b can correspond to the buffer circuit 103a, the ESD protection circuit 104a, and the pad 105a of the first die 100a. In some embodiment, the pad 105a can be interchangeable referred to as a metal pad, a pad pin, a bump pad, or a die-to-die pad.

The buffer circuit 103a can be used to strengthen and stabilize the signals being transmitted in and out of the die 100a. In some embodiments, the buffer circuit 103a can condition the signal, such as inverting it (e.g., inverter buffer) or providing multiple states (e.g., tri-state buffer). In some embodiments, the buffer circuit 103a can provide isolation between circuits, protecting a circuit from the potentially harmful effects of the connected circuit. In some embodiments, the buffer circuit 103a can be changeable referred to as an ESD victim.

In some embodiment, the receiving circuit RX in the buffer circuit 103a can be configured to send a signal on the pad 105a to the logic circuit 102a. The receiving circuit RX can be configured to receive an input enable signal IE. The receiving circuit RX can be enabled to send the signal on the pad 105a to the logic circuit 102a in response to a logic state of the input enable signal IE, and can be disabled from sending the signal on the pad 105a to the logic circuit 102a in response to a different logic state of the input enable signal IE. The transferring circuit TX in the buffer circuit 103a can be configured to send a signal output by the logic circuit 102a to the pad 105a. The transferring circuit TX can be configured to receive an output enable signal OE. The transferring circuit TX can be enabled to send the signal output by the logic circuit 102a to the pad 105a in response to a logic state of the output enable signal OE, and can be disabled from sending the signal output by the logic circuit 102a to the pad 105a in response to a different logic state of the output enable signal OE. Examples of the signal(s) input from or output to the pad 105a include, but are not limited to, data, power, clock, control, or the like. Examples of one or more circuits in at least one of the receiving circuit RX or transferring circuit TX include, but are not limited to, a buffer, a latch, a level shifter, or the like.

In some embodiment, the ESD protection circuit 104a can be configured to protect the other circuits, including the logic circuit 102a, that are electrically coupled to the pad 105a from ESD events occurring on the pad 105a during operation or handling of the first die 100a or IC device 100. By way of example and not limitation, the ESD protection circuit 104a can employ components like diodes to clamp the voltage to a safe level when an ESD event occurs, preventing the voltage spike from reaching and damaging the sensitive parts in the die 100a. In some embodiment, the ESD protection circuit 104a can serves to divert the excess current away from sensitive circuit components. Examples of the ESD protection circuit 104a include, but are not limited to, a diode, a grounded-gate NMOS (ggNMOS), a silicon-controlled rectifier (SCR), or the like. In some embodiments, transistors in the ESD protection circuit 104a can be larger than and/or have a different configuration from the functional transistors or core transistors of the logic circuit 102a to be able to sustain and handle high voltages and/or current of ESD events.

In some embodiment, the first die 100a is electrically coupled to the second die 100b at one or more die-to-die interconnects. In FIG. 1A, a representative die-to-die interconnect is illustrated, and is electrically coupled to the pad 105a of the first die 100a and to a corresponding pad 105b of the second die 100b. As a result, the pad 105a of the first die 100a is electrically coupled to the corresponding pad 105b of the second die 100b through the die-to-die interconnect. In some embodiments, the die-to-die interconnect can be a TSV in one or more dies of the IC device 100.

FIG. 1C is a cross-sectional view of the stacked IC device of FIG. 1A. Each of the first and second dies 100a and 100b may include a substrate 110, one or more devices DE over the substrate 110, contact plugs CP, a multi-level interconnect structure 200, and a pad 105a/105b. The substrate 110 may include wells WR (e.g., n-type wells or p-type wells) therein. The devices DE may include a gate structure G and source/drain regions SD on opposite sides of the gate structure. The devices DE may be located over the wells WR. The contact plugs CP may land on the gate structures G and the source/drain regions SD of the devices DE. The multi-level interconnect structure 200 may be formed over the contact plugs CP. The multi-level interconnect structure 200 may include plural metallization layers (or interconnect layer) stacked one over another. Each of the metallization layers may include metal lines 204 extending horizontally and/or metal vias 206 extending vertically between the metal lines 204. The pad 105a/105b is over the multi-level interconnect structure 200. The metallization layers (or interconnect layer) may include a dielectric layer surrounding the metal lines 204 and the metal vias 206. In some embodiments, the devices DE are arranged to form the buffer circuit 103a/103b and the ESD protection circuit 104a/104b, and the multi-level interconnect structure 200 may electrically connect the buffer circuit 103a/103b and the ESD protection circuit 104a/104b to the pad 105a/105b, through the contact plugs CP.

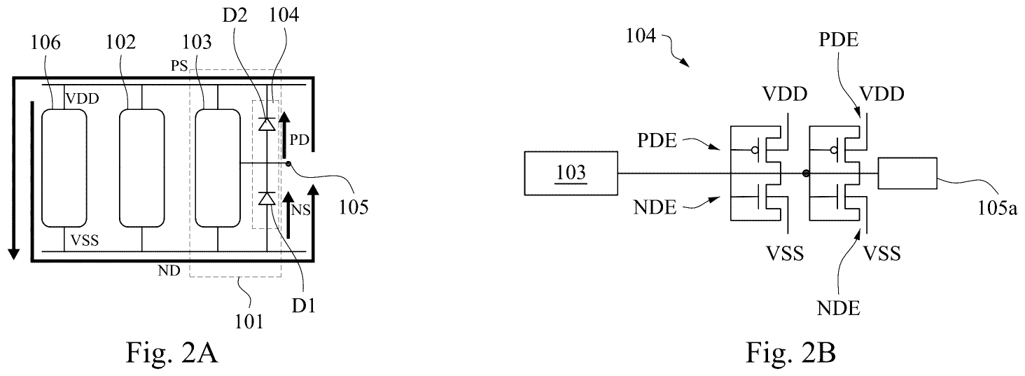

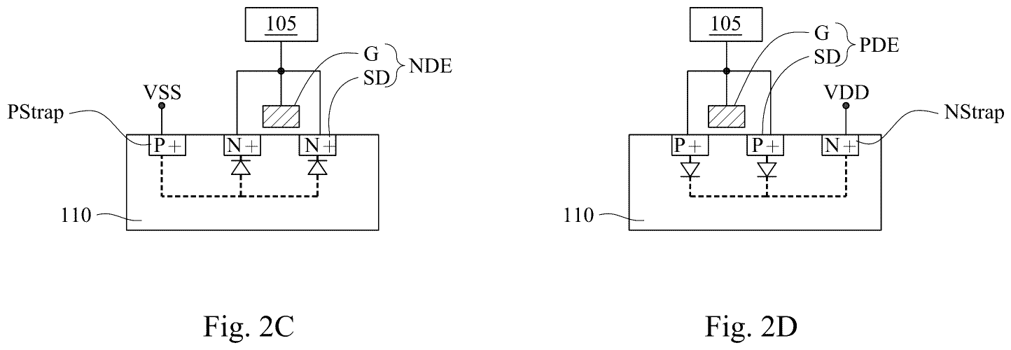

FIG. 2A illustrates a schematic block diagram showing operations of an ESD protection circuit 104. The I/O circuits 101, the logic circuits 102, the buffer circuit 103, ESD protection circuit 104, and the pad 105 may correspond to the I/O circuits 101a/101b, the logic circuits 102a/102b, the buffer circuit 103a/103b, ESD protection circuit 104a/104b, and the pad 105a/105b in the die 100a/100b. The ESD protection circuit 104 may be formed by diodes D1 and D2. The diode D1 is connected between the pad 105 to a low power voltage line VSS, and the diode D2 is connected between the pad 105 to a high power voltage line VDD, in which a voltage of the high power voltage line VDD is higher than a voltage of the low power voltage line VSS. In some embodiments, an ESD power-clamp circuit 106 is placed between the low power voltage line VSS and the high power voltage line VDD to provide low resistance path during ESD events when needed. In some embodiments, the ESD power clamp circuit 106 is constructed by RC-invertor and a BigFET. Through the ESD power-clamp circuit 106, ESD protection can be achieved under VDD-to-VSS (or VSS-to-VDD) ESD stress, as well as different ESD stress conditions from the input/output to VDD/VSS, including positive-to-VSS (PS) mode, negative-to-VSS (NS) mode, positive-to-VDD (PD) mode, and negative-to-VDD (ND) mode. The PS mode, NS mode, PD mode, and the ND mode are respectively indicated as the paths PS, NS, PD, and ND. Therefore, the ESD protection circuit 104 and the ESD power-clamp circuit 106 can provide efficient protection to the logic circuit 102. In the context, the logic circuits 102a, 102b, the buffer circuit 103a, 103b, the ESD protection circuit 104a, 104b, the pad 105a, 105b in the first and second dies 100a and 100b (referring to FIGS. 1A-1C) can be referred to as the logic circuits 102, the buffer circuit 103, the ESD protection circuit 104, the pad 105, respectively. The first and second dies 100a and 100b (referring to FIGS. 1A-1C) may both include the ESD power-clamp circuit 106 in some embodiments.

FIG. 2B illustrates a circuit diagram of the ESD protection circuit 104a in FIG. 2A. FIG. 2C is a cross-sectional view of a portion of the ESD protection circuit 104a of FIG. 2B. FIG. 2D is a cross-sectional view of another portion of the ESD protection circuit 104a of FIG. 2B. The diode D1 can be an n-type device NDE in the devices DE (referring to FIG. 1C), in which the gate structure G and the source/drain regions SD of the n-type device NDE are connected with the pad 105 as shown in FIG. 2C. The diode D2 can be a p-type device PDE in the devices DE (referring to FIG. 1C), in which the gate structure G and the source/drain regions SD of the p-type device PDE are connected with the pad 105 as shown in FIG. 2D.

In FIG. 2C, n-type heavily doped regions N+ are formed in the substrate 110 and serve as the source/drain regions SD of the n-type device NDE. And, a p-type heavily doped region P+ is formed in the substrate 110 and serves as a p-type strap region PStrap connecting the p-type substrate 110 (or a p-type well region if it present) to the low power voltage line VSS.

In FIG. 2D, an n-type well region NW is formed in the substrate 110. P-type heavily doped regions P+ are formed in the substrate 110 and serve as the source/drain regions SD of the p-type device PDE. And, an n-type heavily doped region N+ is formed in the n-type well region NW and serve as an n-type strap region Nstrap connecting the n-type well region NW to the high power voltage line VDD.

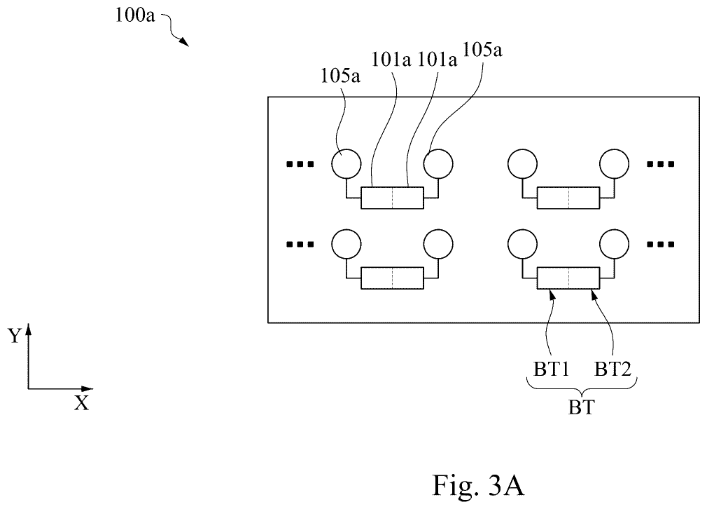

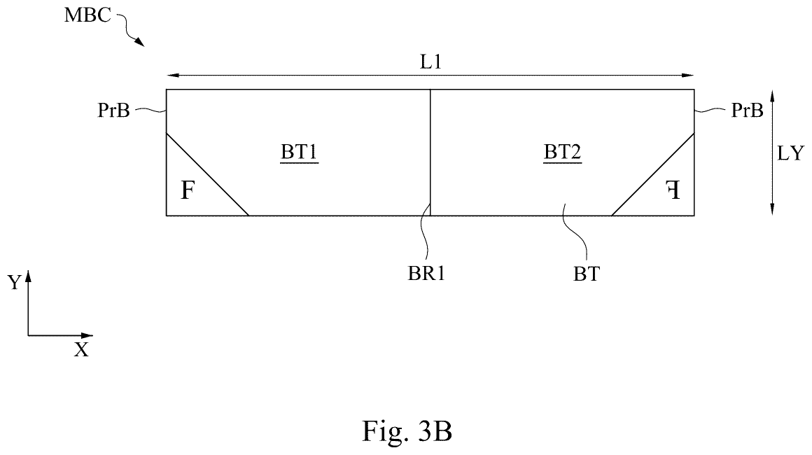

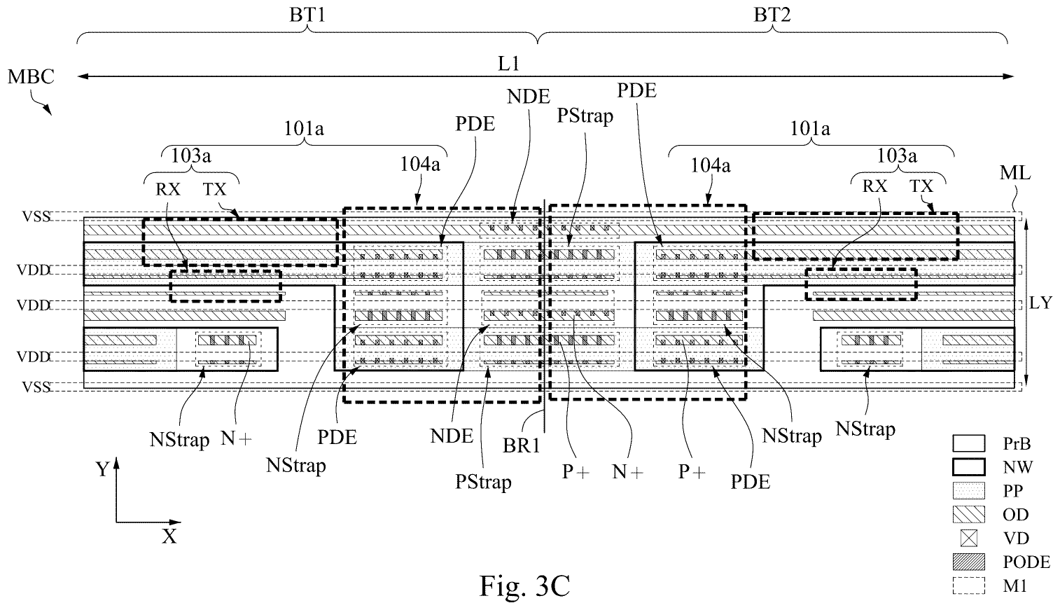

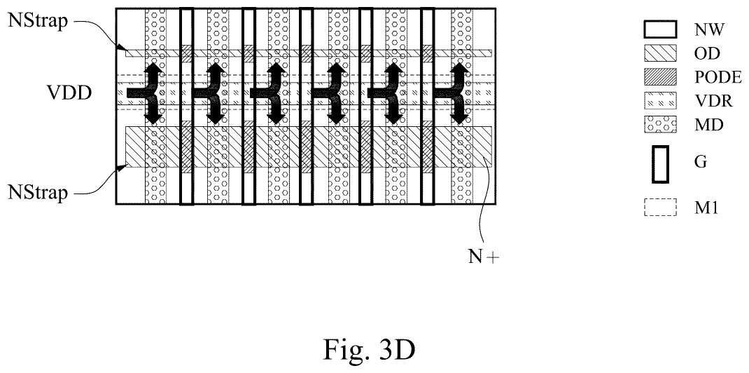

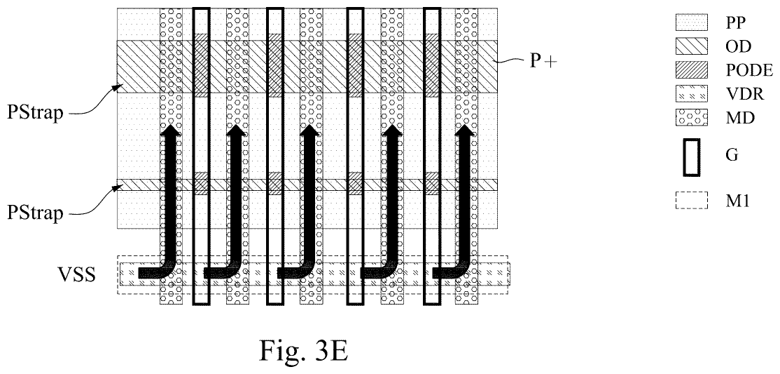

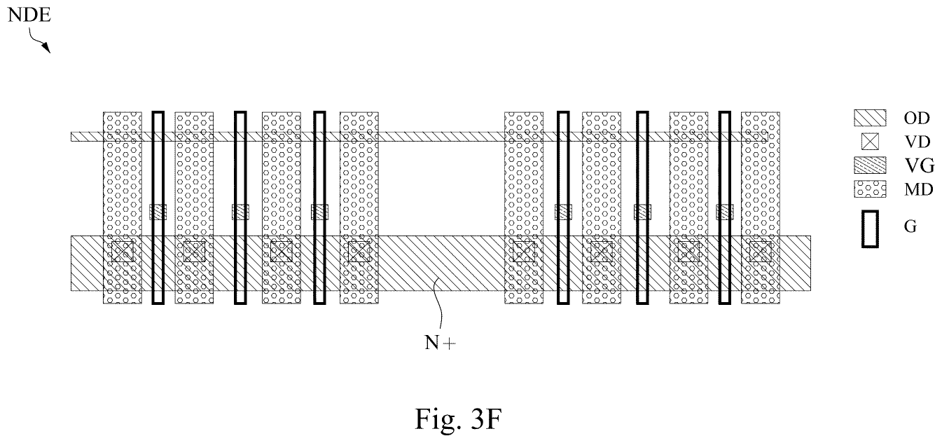

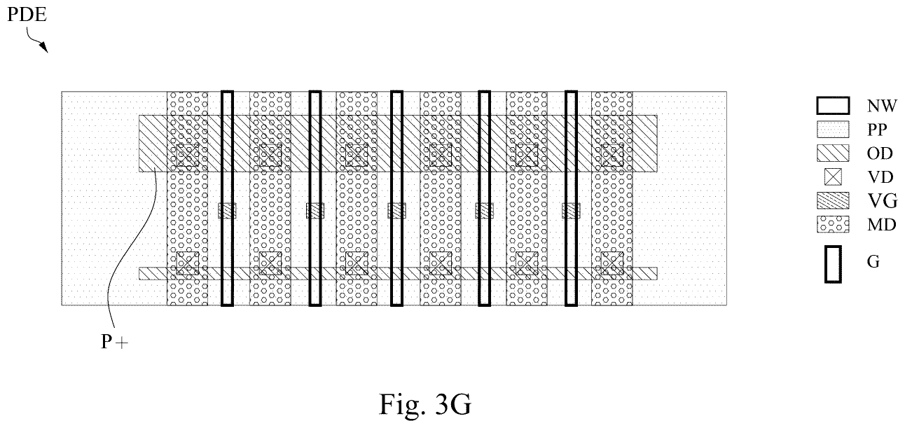

FIG. 3A is a schematic view of an IC device 100a in accordance with some embodiments of the present disclosure. FIG. 3B illustrates a schematic arrangement of a plurality of bits BT in the IC device of FIG. 3A. The annotations “F” in the bits BT indicate orientations of the bits BT. Each of the bits BT, defined by a boundary PrB, includes substantially the same configurations. In some embodiments of the present disclosure, for depicting a layout, some of the bits BT are grouped/arrayed as a multi-bit cell MBC, and the layout can be depicted by repeating the multi-bit cells MBC. In the present embodiments, a multi-bit cell MBC, includes the two bits BT, which are annotated as bits BT1 and BT2 for better illustration. The annotation “F” in the bit BT1 is opposite to the annotation “F” in the bit BT2. This indicates that the bit BT1 is mirror symmetric to the bit BT2, for example, along to a border BR1 between the bits BT1 and BT2. Stated differently, the layouts of the bit BT2 may be obtained by flipping the layouts of the bit BT1. By this symmetric configuration, elements (e.g., the n-type device NDE and the p-type strap region Pstrap) in the I/O circuits 101a of the adjacent bits BT1 and BT2 can be arranged closely, thereby saving regions for the I/O circuits 101a. And, the elements (e.g., the n-type device NDE and the p-type strap region Pstrap) in the I/O circuits 101a of the two bits BT1 and BT2 can share the active regions (e.g., fins), thereby satisfying a number of fins of ESC circuit according to the design rule check (DRC) with reduced regions for the I/O circuits 101a.

In the present embodiments, the mirror symmetric bits BT1 and BT2 are arranged and aligned with each other along a direction X, and the pads 105a connected to the mirror symmetric bits BT1 and BT2 are arranged and aligned with each other along the direction X and spaced apart from each other along the direction X. The pads 105a may have any suitable arrange embodiments in various embodiments. In some embodiments, a length L1 of the multi-bit cell MBC measured along the direction substantially perpendicular to an extension direction of the border BR1 (e.g., the direction X) is greater than a length LY of the multi-bit cell MBC measured along a direction substantially parallel to the extension direction of the border BR1 (e.g., the direction Y).

FIG. 3C shows a layout of the IC device 100a of FIG. 3A. The layouts of the IC device 100a may include active regions OD, n-type well region NW, source/drain contact structures VD, and auxiliary structures PODE on edges of the active regions OD. In the layout, each of the p-type devices PDE includes the active region OD in the n-type well region NW and in a region PP, and each of the n-type devices NDE includes the active region OD outside the n-type well region NW and outside a region PP. The region PP indicates locations of the p-type heavily doped regions P+ (referring to FIGS. 2C and 2D) and the n-type heavily doped regions N+ (referring to FIGS. 2C and 2D). For example, the p-type heavily doped regions P+ would be located on the active regions OD in the region PP, while the n-type heavily doped regions N+ (referring to FIGS. 2C and 2D) would be located on the active regions OD outside the region PP.

In FIG. 3C, each of the bits BT1 and BT2 includes a transferring circuit TX, a receiving circuit RX, and an ESD protection circuit 104a. The transferring circuit TX, the receiving circuit RX, the ESD protection circuit 104a are indicated in FIG. 3C by dashed-line blocks. The transferring circuit TX may include at least one n-type device NDE and at least one p-type device PDE. The receiving circuit RX may include at least one n-type device NDE and at least one p-type device PDE. And, the ESD protection circuit 104a may include at least one n-type device NDE and at least one p-type device PDE. In the present embodiments, the n-type device NDE of the ESD protection circuit 104a of the bit BT1 can be placed adjacent to the n-type device NDE of the ESD protection circuit 104a of the bit BT2. Through the configuration, the region for the ESD protection circuit 104a can be reduced, thereby saving regions for the I/O circuit 101a.

In FIG. 3C, each of the bits BT (the bit BT1/BT2) may include at least one n-type strap region Nstrap and at least one p-type strap region PStrap. In the layout, each of the n-type strap regions Nstrap includes the active region OD in the n-type well region NW and outside the region PP, and each of the p-type strap regions PStrap includes the active region OD outside the n-type well region NW and in the region PP. In the present embodiments, the p-type strap region PStrap of the bit BT1 can be placed adjacent to the p-type strap region PStrap of the bit BT2. Through the configuration, the regions for the p-type strap regions PStrap can be reduced, thereby saving regions for entire circuits.

In FIG. 3C, blocks with imaginary bolded-dashed lines indicates regions of the transferring circuit TX, the receiving circuit RX, and the ESD protection circuit 104a. Blocks with imaginary dashed lines indicates regions of the p-type strap regions PStrap, the n-type strap regions Nstrap, the p-type devices PDE, and the n-type devices NDE. The horizontal strips with dashed lines extending the entire multi-bit cell MBC may indicate regions of the high power rails VDD and the lower power rails VSS. The horizontal strips with bolded-dashed lines may be consider as actual metal lines ML of a metallization layer M1, and indicated as the high power rails VDD and the lower power rails VSS.

FIG. 3D is an enlarged view of an n-type strap region NStrap in an ESD protection circuit 104a in FIG. 3C. FIG. 3E is an enlarged view of a p-type strap region Pstrap in an ESD protection circuit 104a in FIG. 3C. FIG. 3F is an enlarged view of an n-type device NDE in an ESD protection circuit 104a in FIG. 3C. FIG. 3G is an enlarged view of a p-type device PDE in an ESD protection circuit 104a in FIG. 3C. The layouts of the IC device 100a may include contacts MD on heavily doped regions P+/N+ over the active regions OD, conductive structure VDR on the contacts MD, and power rails VSS and VDD over the conductive structure VDR. The layouts of the IC device 100a may further include gate structures G (which correspond to the patterns of the gate structure 130 and 170) and gate via VG over the gate structures G. In the present embodiments, the power rails VSS and VDD are some of metal lines 204 in the bottommost metallization layer of the MLI structure 200. As shown in FIG. 3D, the n-type strap region NStrap (e.g., the heavily doped region N+) can be tied to the high power rail VDD, for example, through the contacts MD and the conductive structure VDR. The arrows in FIG. 3D indicate the current from the high power rail VDD to the n-type strap region NStrap. As shown in FIG. 3D, the p-type strap region Pstrap (e.g., the heavily doped region P+) can be tied to the low power rail VSS, for example, through the contacts MD and the conductive structure VDR. The arrows in FIG. 3E indicate the current from the low power rail VSS to the p-type strap region Pstrap.

The auxiliary structures PODE may be also referred to as poly on diffusion edge structures. The auxiliary structures PODE may be formed over edges of the active region OD. In some embodiment, the auxiliary structures PODE do not constitute any functional feature of one or more active devices formed in the corresponding active region OD. In FIGS. 3D and 3E, with the configuration of the auxiliary structures PODE, there may be no functional gate structures G adjoins the n-type strap region NStrap (e.g., the heavily doped region N+) and the p-type strap region Pstrap (e.g., the heavily doped region P+) over the active regions OD. In FIG. 3F, the n-type device NDE may include gate structures G and heavily doped regions N+ over the active regions OD. In FIG. 3G, the p-type device PDE may include gate structures G and heavily doped regions P+ over the active regions OD.

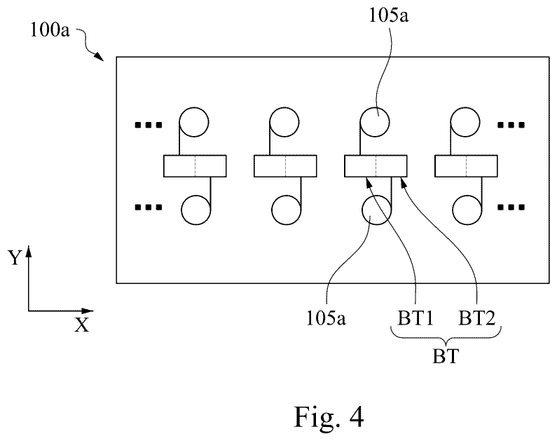

FIG. 4 is a schematic view of an IC device in accordance with some embodiments of the present disclosure. Details of the present embodiments are similar to those illustrated in the embodiments of FIGS. 3A-3C, except that while the mirror symmetric bits BT1 and BT2 are arranged and aligned with each other along the direction X, and the pads 105a connected to the mirror symmetric bits BT1 and BT2 are arranged and aligned with each other along the direction Y and spaced apart from each other along the direction Y. The direction Y may be substantially perpendicular to the direction X. Other details of the present embodiments are similar to that of the embodiments of FIGS. 3A-3C, and therefore not repeated herein.

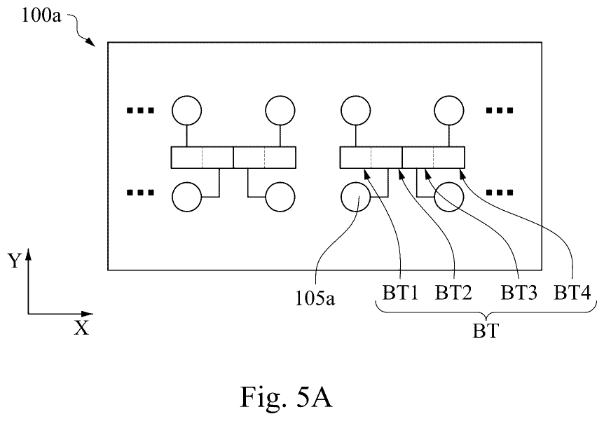

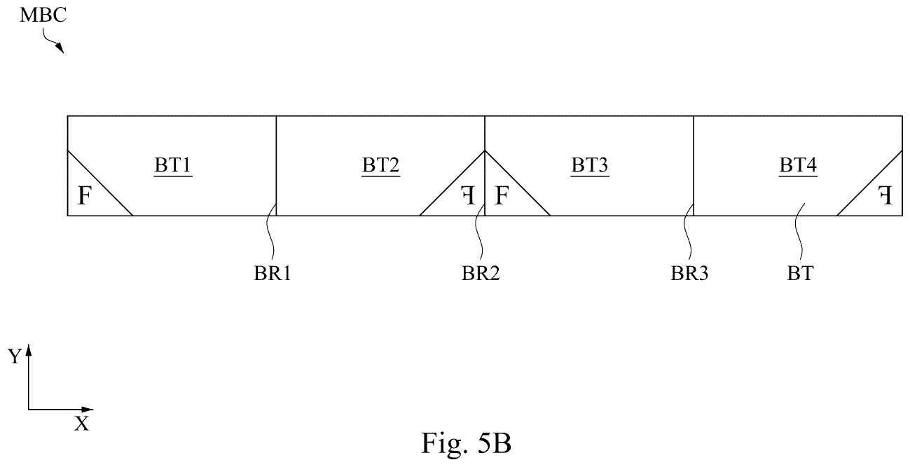

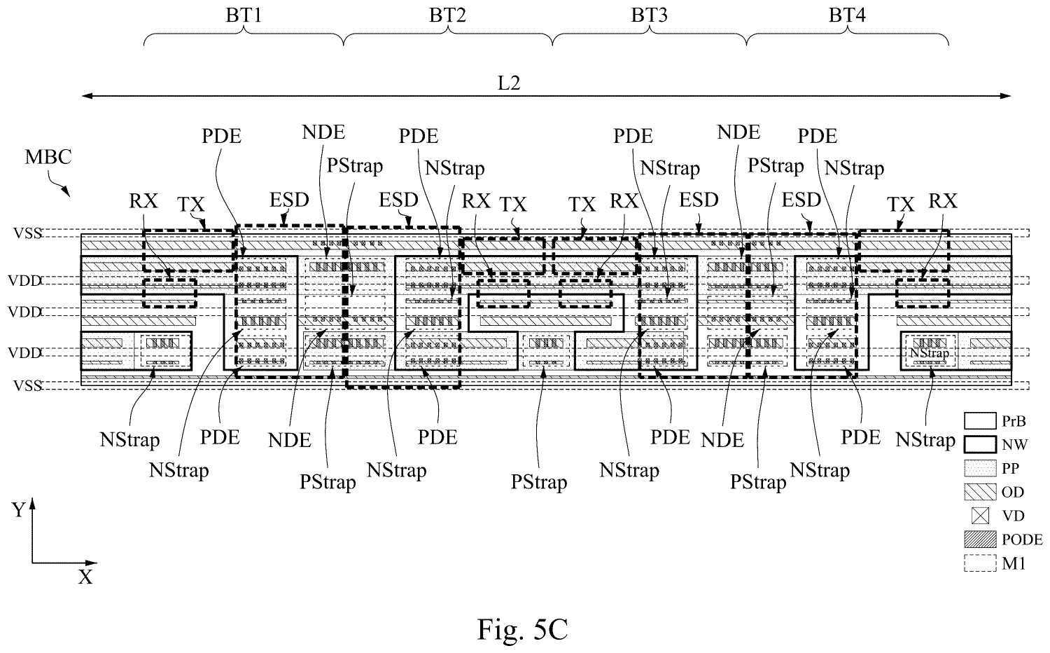

FIG. 5A is a schematic view of an IC device in accordance with some embodiments of the present disclosure. FIG. 5B illustrates a schematic arrangement of a plurality of bits in the IC device of FIG. 5A. Details of the present embodiments are similar to those illustrated in the embodiments of FIGS. 3A-3C, except that the multi-bit cell MBC includes the four bits BT in the present embodiments. The four bits BT are annotated as bits BT1-BT4 for better illustration. The annotation “F” in the bit BT1 is opposite to the annotation “F” in the bit BT2, the annotation “F” in the bit BT2 is opposite to the annotation “F” in the bit BT3, and the annotation “F” in the bit BT3 is opposite to the annotation “F” in the bit BT4. This indicates that the bit BT1 is mirror symmetric to the bit BT2, for example, along to a border BR1 between the bits BT1 and BT2; the bit BT2 is mirror symmetric to the bit BT3, for example, along to a border BR2 between the bits BT2 and BT3; and the bit BT3 is mirror symmetric to the bit BT4, for example, along to a border BR3 between the bits BT3 and BT4. By this symmetric configuration, elements (e.g., the n-type device NDE and the p-type strap region Pstrap) in the I/O circuits 101a of the adjacent bits BT1 and BT2 can be arranged closely, elements (e.g., the transferring circuit TX, the receiving circuit RX, and the p-type strap region Pstrap) in the I/O circuits 101a of the adjacent bits BT2 and BT3 can be arranged closely, and elements (e.g., the n-type device NDE and the p-type strap region Pstrap) in the I/O circuits 101a of the adjacent bits BT3 and BT4 can be arranged closely, thereby saving regions for the I/O circuits 101a. In the present embodiments, the mirror symmetric bits BT1-BT4 are arranged and aligned with each other along a direction X, and the pads 105a connected to the mirror symmetric bits BT1-BT4 are arranged spaced apart from each other. The pads 105a may have any suitable arrange embodiments in various embodiments.

FIG. 5C shows a layout of the IC device of FIG. 5A. In FIG. 5C, each of the bits BT1-BT4 includes a transferring circuit TX, a receiving circuit RX, and an ESD protection circuit 104a. The transferring circuit TX, the receiving circuit RX, the ESD protection circuit 104a are indicated in FIG. 5C by dashed-line blocks. The transferring circuit TX may include at least one n-type device NDE and at least one p-type device PDE. The receiving circuit RX may include at least one n-type device NDE and at least one p-type device PDE. And, the ESD protection circuit 104a may include at least one n-type device NDE and at least one p-type device PDE. In the present embodiments, the n-type device NDE of the ESD protection circuit 104a of the bit BT1 can be placed adjacent to the n-type device NDE of the ESD protection circuit 104a of the bit BT2. The n-type device NDE of the ESD protection circuit 104a of the bit BT3 can be placed adjacent to the n-type device NDE of the ESD protection circuit 104a of the bit BT4. Through the configuration, the region for the ESD protection circuit 104a can be reduced, thereby saving regions for the I/O circuit 101a.

In FIG. 5C, each of the bits BT1-BT4 may include plural n-type strap regions Nstrap and plural p-type strap regions PStrap. In the layout, each of the n-type strap regions Nstrap includes the active region OD in the n-type well region NW and outside the region PP, and each of the p-type strap regions PStrap includes the active region OD outside the n-type well region NW and in the region PP. In the present embodiments, one of the p-type strap regions PStrap of the bit BT1 can be placed adjacent to one of the p-type strap regions of the bit BT2. One of the p-type strap regions PStrap of the bit BT3 can be placed adjacent to one of the p-type strap regions PStrap of the bit BT4. One of the p-type strap regions PStrap of the bit BT2 can be placed adjacent to one of the p-type strap regions PStrap of the bit BT3. Through the configuration, the regions for the p-type strap regions PStrap can be reduced, thereby saving regions for entire circuits.

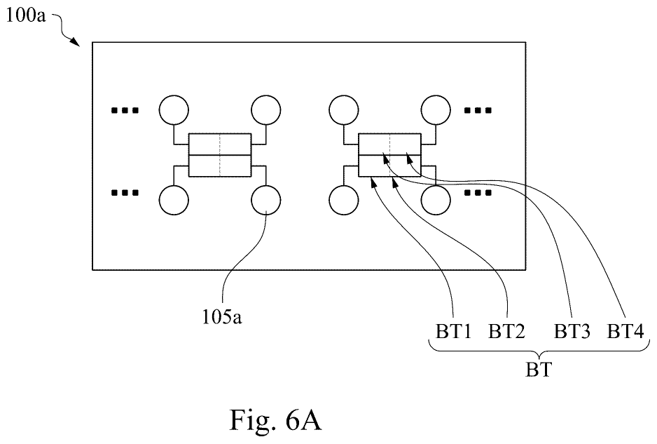

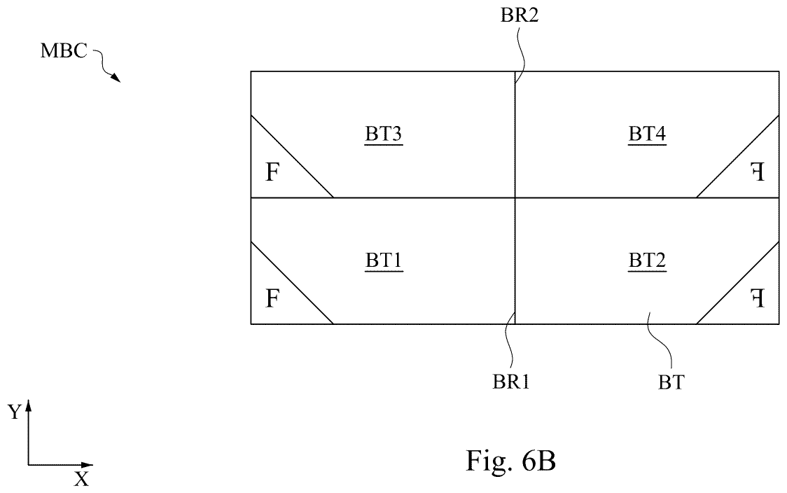

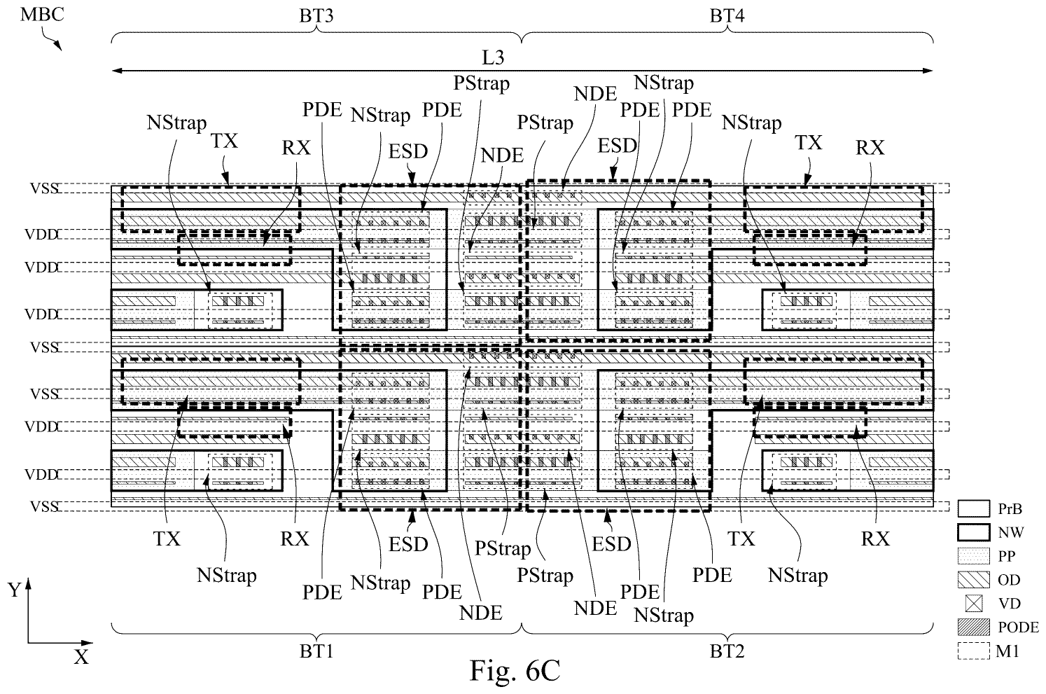

FIG. 6A is a schematic view of an IC device 100a in accordance with some embodiments of the present disclosure. FIG. 6B illustrates a schematic arrangement of a plurality of bits in the IC device of FIG. 6A. Details of the present embodiments are similar to those illustrated in the embodiments of FIGS. 3A-3C, except that the multi-bit cell MBC includes the four bits BT in the present embodiments. The four bits BT are annotated as bits BT1-BT4 for better illustration. The annotation “F” in the bit BT1 is opposite to the annotation “F” in the bit BT2, and the annotation “F” in the bit BT3 is opposite to the annotation “F” in the bit BT4. This indicates that the bit BT1 is mirror symmetric to the bit BT2, for example, along to a border BR1 between the bits BT1 and BT2; and the bit BT3 is mirror symmetric to the bit BT4, for example, along to a border BR2 between the bits BT3 and BT4. By this symmetric configuration, elements (e.g., the n-type device NDE and the p-type strap region Pstrap) in the I/O circuits 101a of the adjacent bits BT1 and BT2 can be arranged closely, and elements (e.g., the n-type device NDE and the p-type strap region Pstrap) in the I/O circuits 101a of the adjacent bits BT3 and BT4 can be arranged closely, thereby saving regions for the I/O circuits 101a. In the present embodiments, the mirror symmetric bits BT1 and BT2 are arranged and aligned with each other along the direction X, the mirror symmetric bits BT3 and BT4 are arranged and aligned with each other along the direction X, the bits BT1 and BT3 are arranged and aligned with each other along the direction Y, and the bits BT2 and BT4 are arranged and aligned with each other along the direction Y. The pads 105a connected to the mirror symmetric bits BT1-4 are arranged spaced apart from each other. The pads 105a may have any suitable arrange embodiments in various embodiments.

FIG. 6C shows a layout of the IC device 100a of FIG. 6A. In FIG. 6C, each of the bits BT1-BT4 includes a transferring circuit TX, a receiving circuit RX, and an ESD protection circuit 104a. The transferring circuit TX, the receiving circuit RX, the ESD protection circuit 104a are indicated in FIG. 6C by dashed-line blocks. The transferring circuit TX may include at least one n-type device NDE and at least one p-type device PDE. The receiving circuit RX may include at least one n-type device NDE and at least one p-type device PDE. And, the ESD protection circuit 104a may include at least one n-type device NDE and at least one p-type device PDE. In the present embodiments, the n-type device NDE of the ESD protection circuit 104a of the bit BT1 can be placed adjacent to the n-type device NDE of the ESD protection circuit 104a of the bit BT2. The n-type device NDE of the ESD protection circuit 104a of the bit BT3 can be placed adjacent to the n-type device NDE of the ESD protection circuit 104a of the bit BT4. Through the configuration, the region for the ESD protection circuit 104a can be reduced, thereby saving regions for the I/O circuit 101a.

In FIG. 6C, each of the bits BT1-BT4 may include plural n-type strap regions Nstrap and plural p-type strap regions PStrap. In the layout, each of the n-type strap regions Nstrap includes the active region OD in the n-type well region NW and outside the region PP, and each of the p-type strap regions PStrap includes the active region OD outside the n-type well region NW and in the region PP. In the present embodiments, one of the p-type strap regions PStrap of the bit BT1 can be placed adjacent to one of the p-type strap regions of the bit BT2. One of the p-type strap regions PStrap of the bit BT3 can be placed adjacent to one of the p-type strap regions PStrap of the bit BT4. Through the configuration, the regions for the p-type strap regions PStrap can be reduced, thereby saving regions for entire circuits.

Comparing the multi-bit cells MBC in FIGS. 3C, 5C, and 6C, the lengths L2 of the four-bit cells MBC in FIG. 5C is less than twice the lengths L1 of the two-bit cells MBC in FIG. 3C. And, the lengths of the four-bit cells MBC L3 in FIG. 6C is less than the lengths L1 of the two-bit cells MBC in FIG. 3C. Arranging the more bits (e.g., four bits) in a repeating cell can save more lengths/space per bit than arranging less bits (e.g., two bits) in a repeating cell.

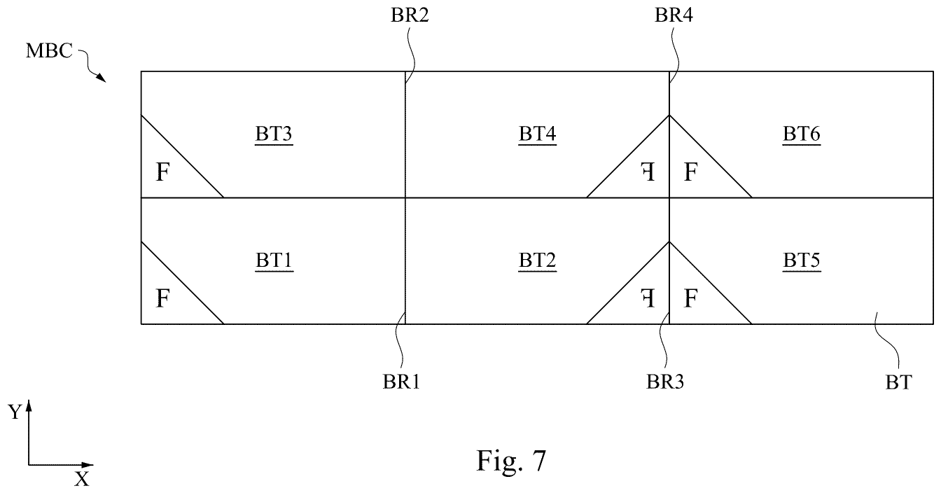

FIG. 7 illustrates a schematic arrangement of a plurality of bits in an IC device in accordance with some embodiments of the present disclosure. Details of the present embodiments are similar to those illustrated in the embodiments of FIGS. 6A-6C, except that the multi-bit cell MBC includes the six bits BT in the present embodiments. The six bits BT are annotated as bits BT1-BT6 for better illustration. In the present embodiments, the bits BT1, BT2, and BT5 are arranged and aligned with each other along the direction X, the bits BT3, BT4, and BT6 are arranged and aligned with each other along the direction X, the bits BT1 and BT3 are arranged and aligned with each other along the direction Y, the bits BT2 and BT4 are arranged and aligned with each other along the direction Y, and the bits BT5 and BT6 are arranged and aligned with each other along the direction Y. The annotation “F” in the bit BT2 is opposite to the annotations “F” in the bits BT1 and BT5, and the annotation “F” in the bit BT4 is opposite to the annotation “F” in the bits BT3 and BT6. This indicates that the bit BT2 is mirror symmetric to the bits BT1 and BT5, for example, along to a border BR1 between the bits BT1 and BT2 and a border BR3 between the bits BT2 and BT5; and the bit BT4 is mirror symmetric to the bit BT3 and BT6, for example, along to a border BR2 between the bits BT3 and BT4 and a border BR4 between the bits BT4 and BT6. By this symmetric configuration, elements in the I/O circuits 101a of the adjacent two bits can be arranged closely, thereby saving regions for the I/O circuits 101a. Other details of the present embodiments are similar to those described above, and therefore not repeated herein.

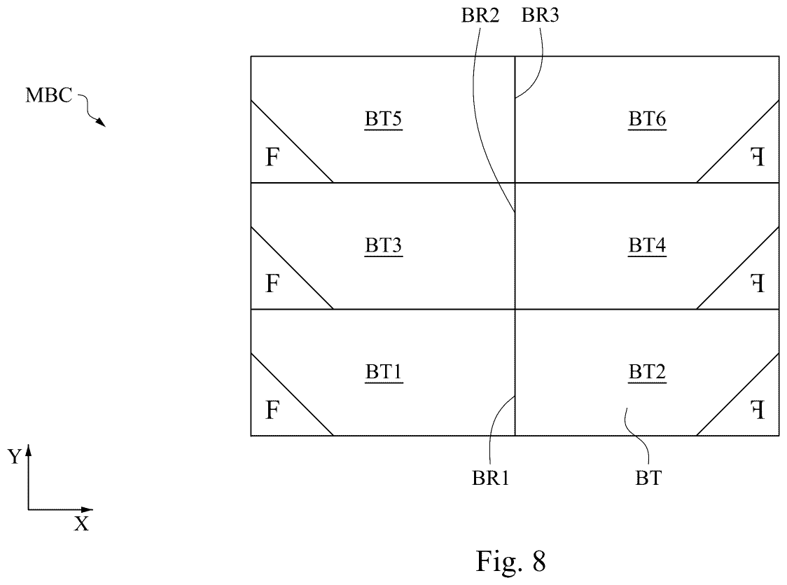

FIG. 8 illustrates a schematic arrangement of a plurality of bits in an IC device in accordance with some embodiments of the present disclosure. Details of the present embodiments are similar to those illustrated in the embodiments of FIGS. 6A-6C, except that the multi-bit cell MBC includes the six bits BT in the present embodiments. The six bits BT are annotated as bits BT1-BT6 for better illustration. In the present embodiments, the bits BT1 an BT2 are arranged and aligned with each other along the direction X, the bits BT3 and BT4 are arranged and aligned with each other along the direction X, the bits BT5 and BT6 are arranged and aligned with each other along the direction X, the bits BT1, BT3, BT5 are arranged and aligned with each other along the direction Y, the bits BT2, BT4, BT6 are arranged and aligned with each other along the direction Y. The annotation “F” in the bit BT1 is opposite to the annotation “F” in the bit BT2, the annotation “F” in the bit BT3 is opposite to the annotation “F” in the bit BT4, and the annotation “F” in the bit BT5 is opposite to the annotation “F” in the bit BT6. This indicates that the bit BT1 is mirror symmetric to the bit BT2, for example, along to a border BR1 between the bit BT1 and BT2; the bit BT3 is mirror symmetric to the bit BT4, for example, along to a border BR2 between the bits BT3 and BT4; the bit BT5 is mirror symmetric to the bit BT6, for example, along to a border BR3 between the bits BT5 and BT6. By this symmetric configuration, elements in the I/O circuits 101a of the adjacent two bits can be arranged closely, thereby saving regions for the I/O circuits 101a. Other details of the present embodiments are similar to those described above, and therefore not repeated herein.

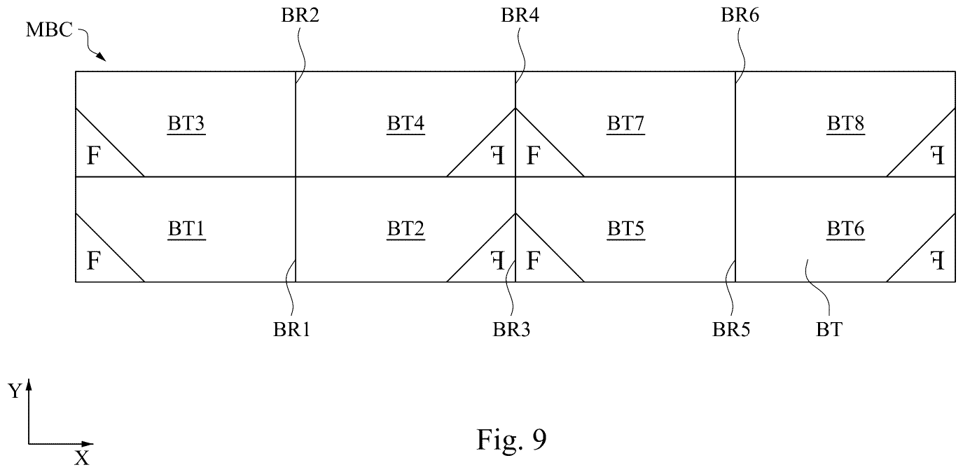

FIG. 9 illustrates a schematic arrangement of a plurality of bits in an IC device in accordance with some embodiments of the present disclosure. Details of the present embodiments are similar to those illustrated in the embodiments of FIGS. 6A-6C, except that the multi-bit cell MBC includes the eight bits BT in the present embodiments. The eight bits BT are annotated as bits BT1-BT8 for better illustration. In the present embodiments, the bits BT1, BT2, BT5, and BT6 are arranged and aligned with each other along the direction X, the bits BT3, BT4, BT7, and BT8 are arranged and aligned with each other along the direction X, the bits BT1 and BT3 are arranged and aligned with each other along the direction Y, the bits BT2 and BT4 are arranged and aligned with each other along the direction Y, and the bits BT5 and BT7 are arranged and aligned with each other along the direction Y, and the bits BT6 and BT8 are arranged and aligned with each other along the direction Y. The annotations “F” in the bits BT1-BT8 indicates that two of the bits BT1-BT8 neighboring each other are mirror symmetric to each other along one of the border BR1-BR6 between said two of the bits BT1-BT8. By this symmetric configuration, elements in the I/O circuits 101a of the adjacent two bits can be arranged closely, thereby saving regions for the I/O circuits 101a. Other details of the present embodiments are similar to those described above, and therefore not repeated herein.

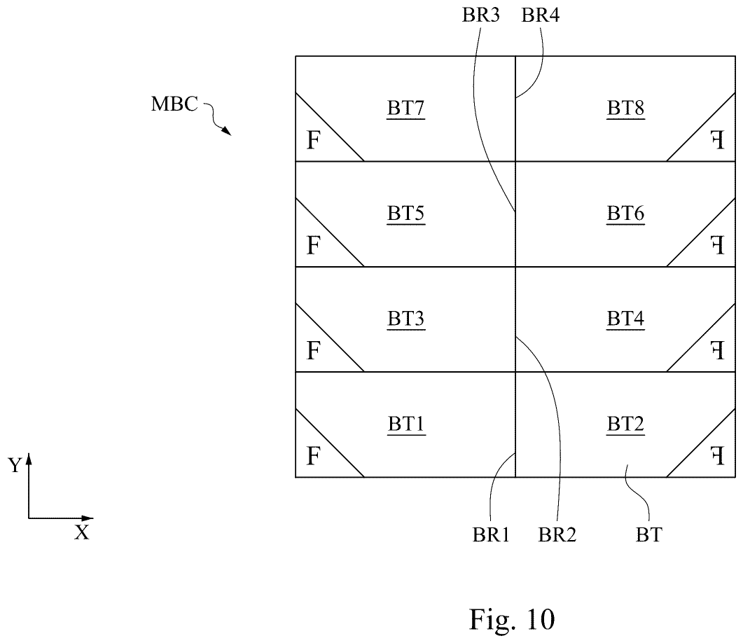

FIG. 10 illustrates a schematic arrangement of a plurality of bits in an IC device in accordance with some embodiments of the present disclosure. Details of the present embodiments are similar to those illustrated in the embodiments of FIGS. 6A-6C, except that the multi-bit cell MBC includes the eight bits BT in the present embodiments. The eight bits BT are annotated as bits BT1-BT8 for better illustration. In the present embodiments, the bits BT1 and BT2 are arranged and aligned with each other along the direction X, the bits BT3 and BT4 are arranged and aligned with each other along the direction X, the bits BT5 and BT6 are arranged and aligned with each other along the direction X, the bits BT7 and BT8 are arranged and aligned with each other along the direction X, the bits BT1, BT3, BT5, BT7 are arranged and aligned with each other along the direction Y, and the bits BT2, BT4, BT6, BT8 are arranged and aligned with each other along the direction Y. The annotations “F” in the bits BT1-BT8 indicates that the bit BT1/BT3/BT5/BT7 and the bit BT2/BT4/BT6/BT8 are mirror symmetric to each other along the border BR1/BR2/BR3/BR4 between the bit BT1/BT3/BT5/BT7 and the bit BT2/BT4/BT6/BT8. By this symmetric configuration, elements in the I/O circuits 101a of the adjacent two bits can be arranged closely, thereby saving regions for the I/O circuits 101a. Other details of the present embodiments are similar to those described above, and therefore not repeated herein.

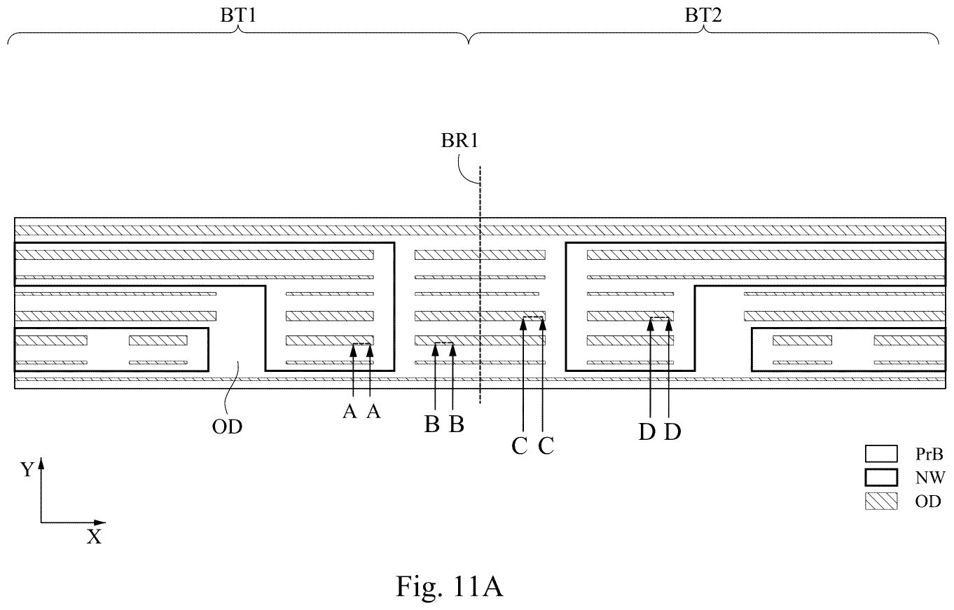

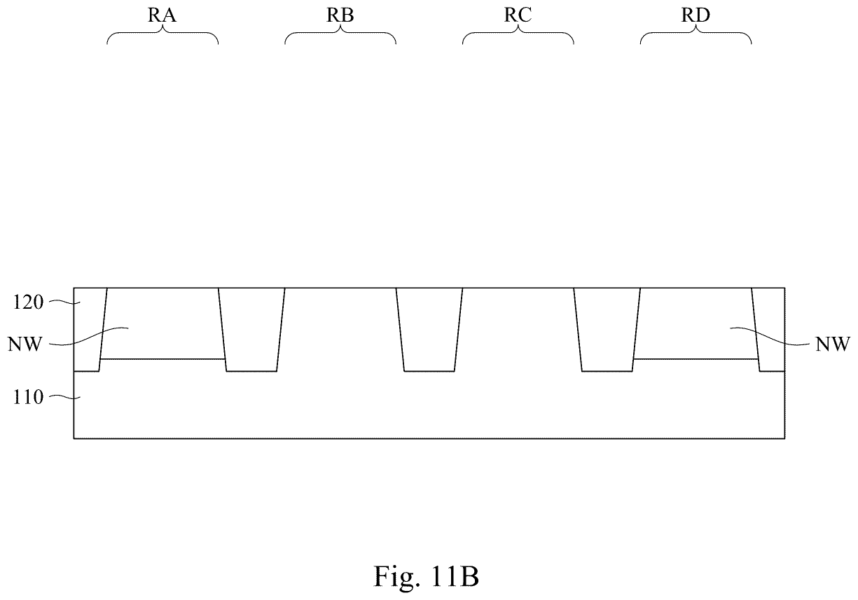

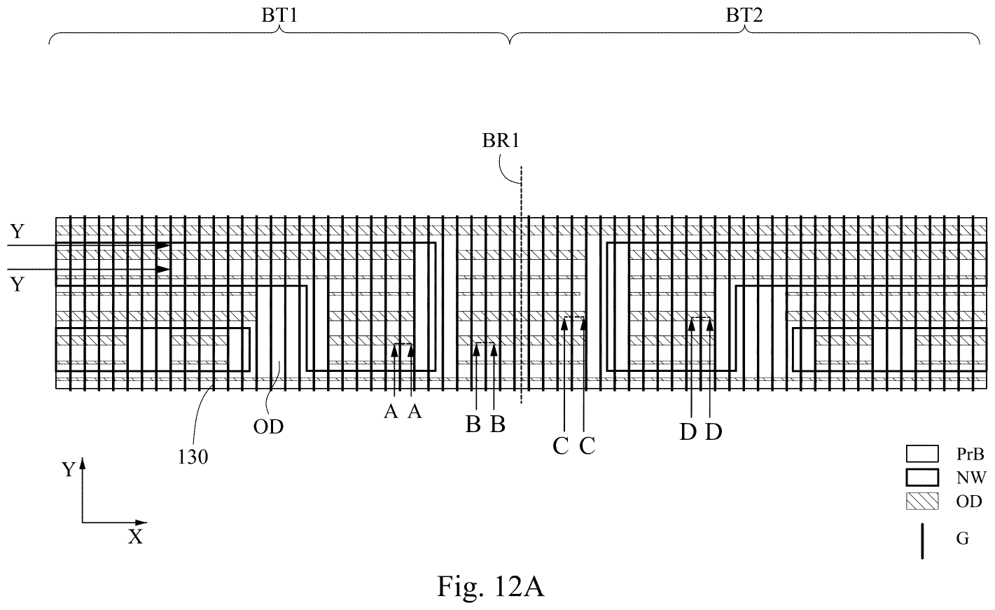

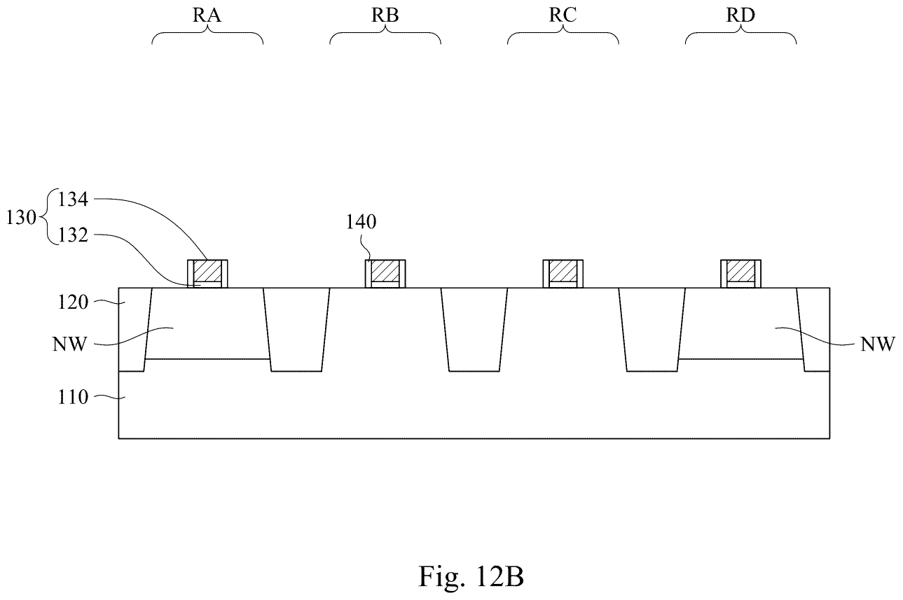

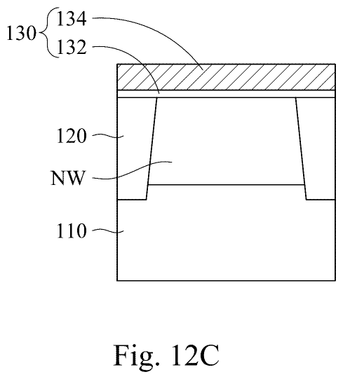

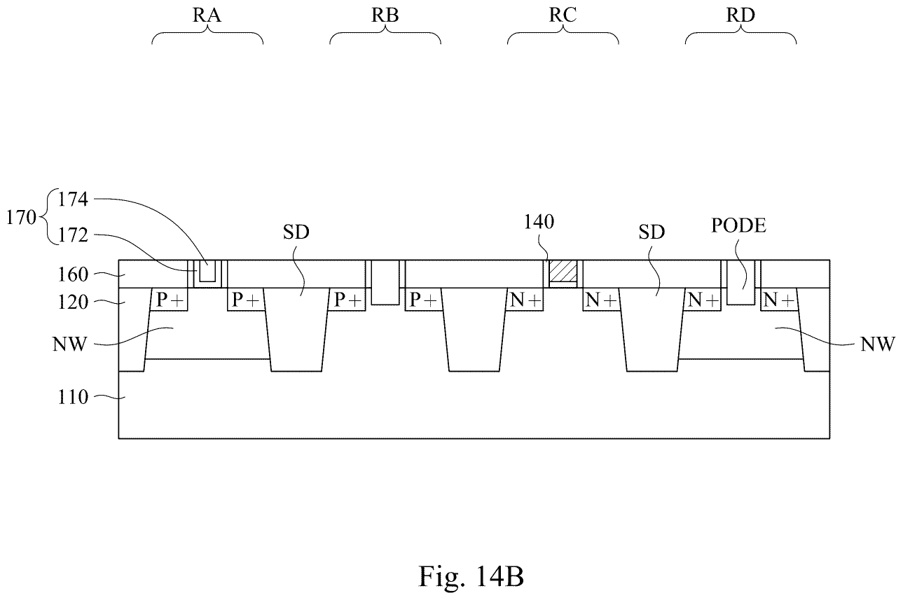

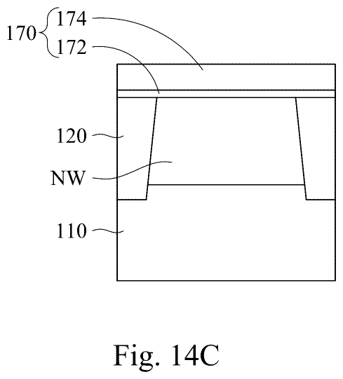

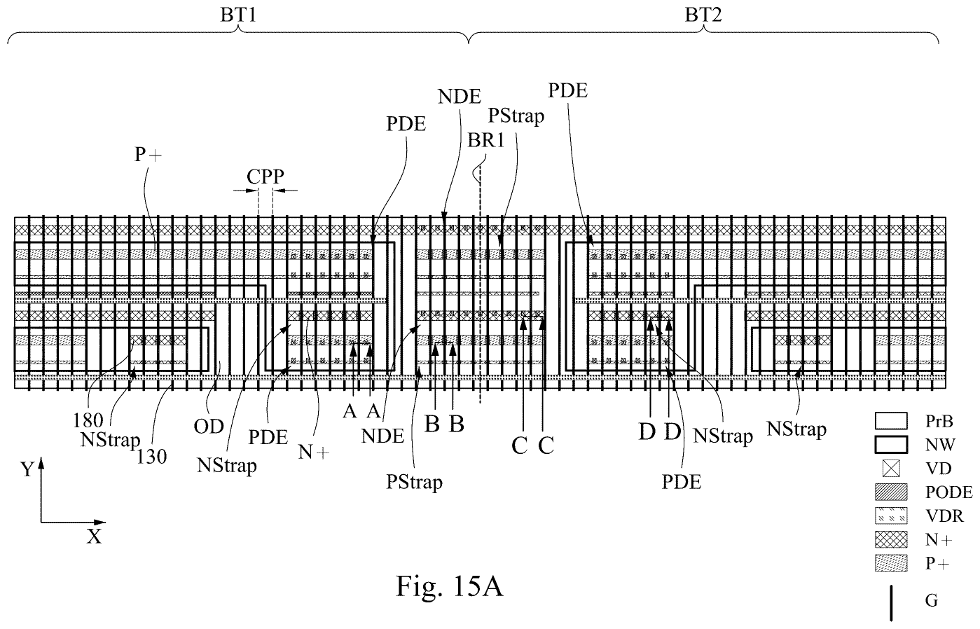

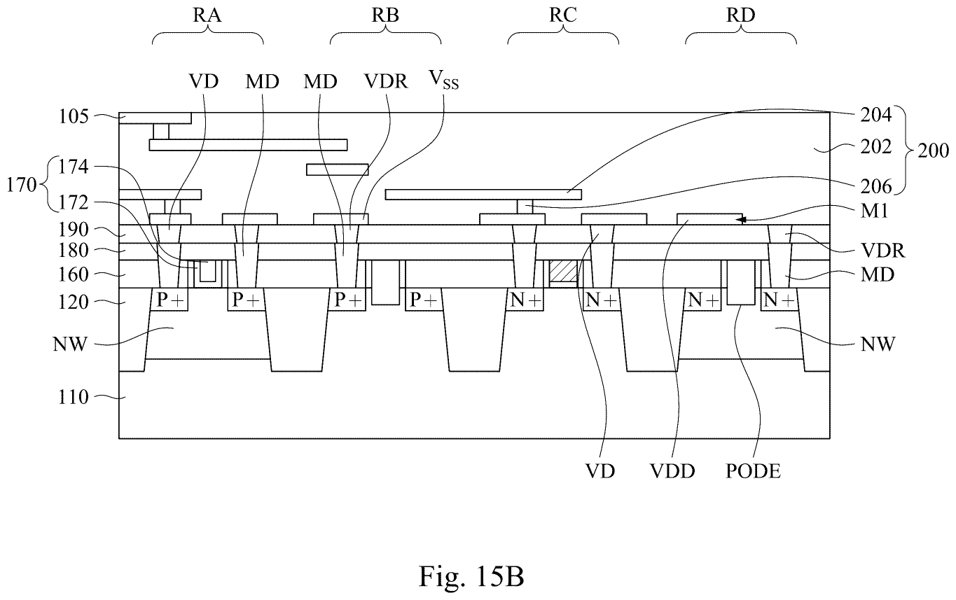

FIGS. 11A-15B illustrate layouts and cross-sectional views of an integrated circuit structure at intermediate stages of manufacturing process according to some embodiments of the present disclosure. FIGS. 11A, 12A, 13A, 14A, and 15A are layouts of the integrated circuit structure at the intermediate stages of the manufacturing process according to some embodiments of the present disclosure. The layouts of FIGS. 11A, 12A, 13A, 14A, and 15A correspond to a layout of a multi-bit cell MBC as shown in FIG. 3C. In some embodiments, the layouts of FIGS. 11A, 12A, 13A, 14A, and 15A may considered as top views of the integrated circuit structure. FIGS. 11B, 12B, 13B, 14B, and 15B illustrate cross-sectional views including regions RA, RB, RC, and RD, respectively taken along line A-A, B-B, C-C, and D-D in FIGS. 11A, 12A, 13A, 14A, and 15A, respectively. FIGS. 12C and 14C illustrate cross-sectional views respectively taken along line Y-Y in FIGS. 12C and 14C, respectively. It is understood that additional steps may be provided before, during, and after the steps shown in FIGS. 11A-15B, and some of the steps described below can be replaced or eliminated for additional embodiments of the method. The order of the operations/processes may be interchangeable. The regions RA, RB, RC, and RD respective corresponds to the regions for the p-type device PDE in the ESD protection circuit, the p-type strap region PStrap, the n-type device NDE in the ESD protection circuit, and the n-type strap region NStrap, as shown in FIG. 15A.

Reference is made to FIGS. 11A and 11B. A substrate 110 is provided, and isolation structures 120 are formed in the substrate 110. In some embodiments, the substrate 110 can be a semiconductor substrate, such as a bulk silicon substrate, a germanium substrate, a compound semiconductor substrate, or other suitable substrate. The substrate 110 may include an epitaxial layer overlying a bulk semiconductor, a silicon germanium layer overlying a bulk silicon, a silicon layer overlying a bulk silicon germanium, or a semiconductor-on-insulator (SOI) structure. The substrate 110 may optionally doped with impurity ions such that it is lightly n-type or lightly p-type. For example, an n-type well region NW is formed in the substrate 110.

Isolation structures 120 are formed in the substrate 110 to separate and electrically isolate plural active regions OD of the substrate 110 from each other. As shown in FIG. 11A, the active regions OD extend along the direction X, and the isolation structures 120 surround the active regions OD. The isolation structures 120 may include shallow trench isolation (STI) regions as shown. For example, formation of the isolation structures 120 may include etching trenches in the substrate 110, and then filling the trenches with a dielectric material, such as oxide. A planarization process may then be used to remove excess dielectric and to thereby confine this dielectric to the trench boundaries. In present embodiments, the isolation structures 120 may have top surfaces level with the top surface of the active regions OD. In some other embodiments, the active regions OD may extend above the top surface of the isolation structures 120, and the active regions OD may be referred to as semiconductor fins surrounded by the isolation structures 120.

Reference is made to FIGS. 12A-12C. A plurality of dummy gate structures 130 are formed around the active regions OD of the substrate 110. As shown in FIG. 12A, the dummy gate structures 130 extend along the direction Y across the active regions OD and the isolation structures 120. In some embodiments, each of the dummy gate structure 130 includes a dummy gate 134 and a gate dielectric 132 underlying the dummy gate 134. The dummy gates 134 may include polycrystalline-silicon (poly-Si) or poly-crystalline silicon-germanium (poly-SiGe). Further, the dummy gates 134 may be doped poly-silicon with uniform or non-uniform doping. The gate dielectrics 132 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof.

In some embodiments, the dummy gate structures 130 may be formed by, for example, forming a stack of a gate dielectric layer and a dummy gate material layer over the substrate 110. A patterned mask is formed over the stack of gate dielectric layer and dummy gate material layer. The patterned mask may be a hard mask (HM) layer patterned through suitable photolithography process. For example, the patterned mask may include silicon nitride, silicon oxy nitride, the like, or the combination thereof. Then, the gate dielectric layer and the dummy gate material layer may be patterned using one or more etching processes, such as one or more dry plasma etching processes or one or more wet etching processes. During the etching process, the patterned mask may act as an etching mask. At least one parameter, such as etchant, etching temperature, etching solution concentration, etching pressure, source power, radio frequency (RF) bias voltage, etchant flow rate, of the patterning (or etching) recipe can be tuned. For example, dry etching process, such as plasma etching, may be used to etch the dummy gate material layer and the gate dielectric layer until the active regions OD and the isolation structures 120 are exposed.

Gate spacers 140 are formed on opposite sidewall of the dummy gate structures 130. Formation of the gate spacers 140 may include conformally depositing a spacer material layer on top and sidewalls of the dummy gate structures 130, followed by an anisotropic etching process. The spacer material layer may include a dielectric material such as silicon oxide, silicon nitride, silicon oxynitride, SiCN films, silicon oxycarbide, SiOCN films, and/or combinations thereof. Portions of the spacer material layer directly above the dummy gate structures 130 may be completely removed by this anisotropic etching process. Portions of the spacer material layer on sidewalls of the dummy gate structures 130 may remain, forming gate spacers, which are denoted as the gate spacers 140, for the sake of simplicity.

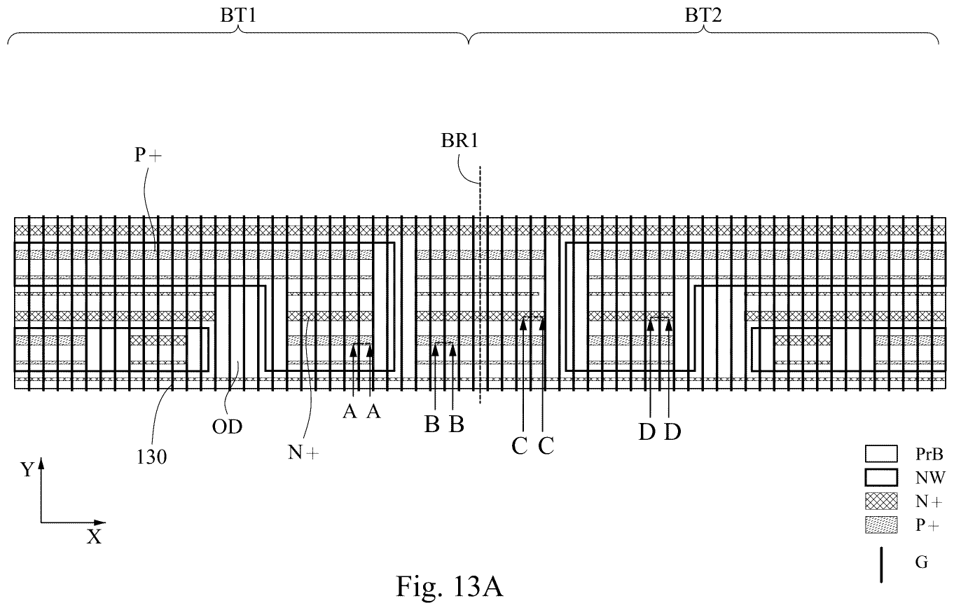

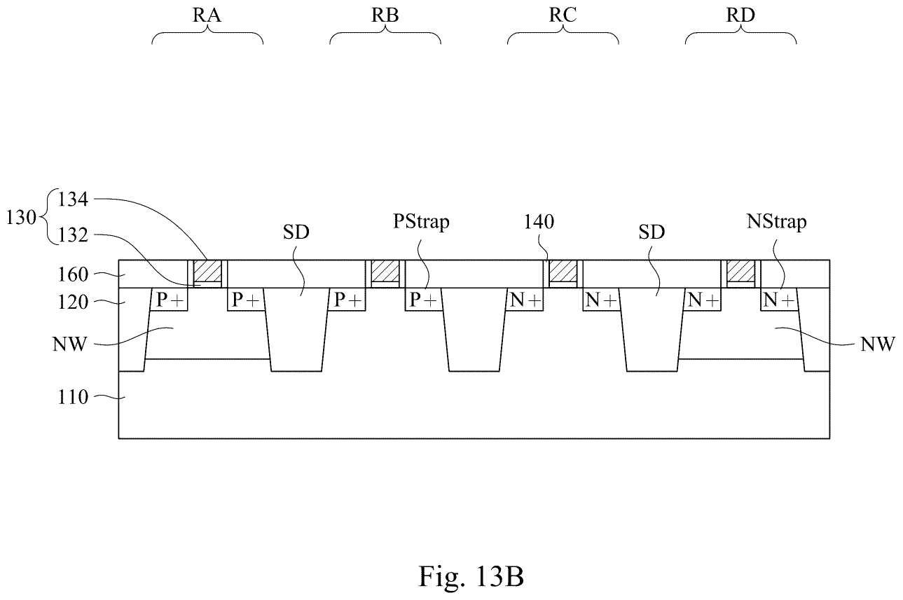

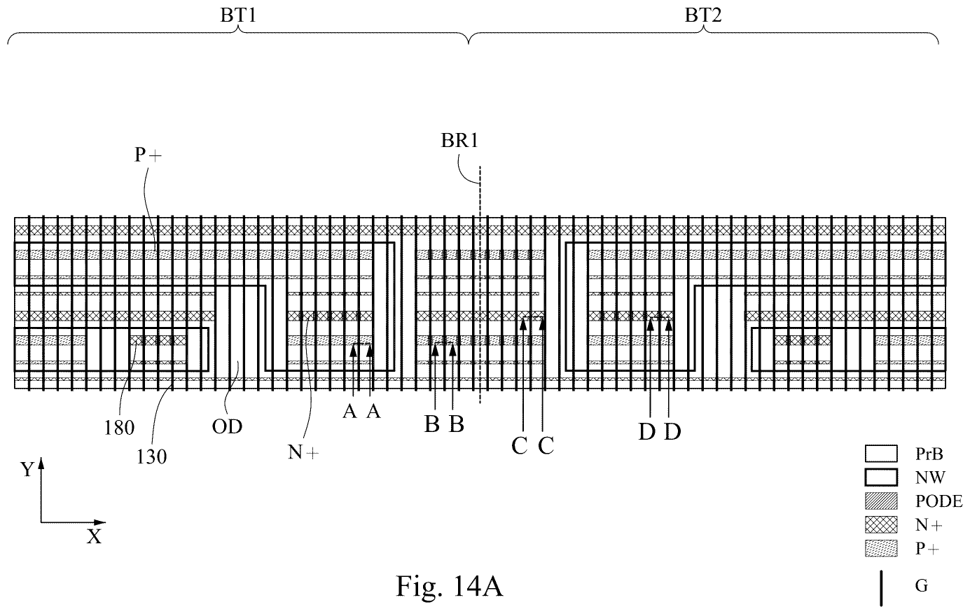

Reference is made to FIGS. 13A and 13B. P-type heavily doped regions P+ and n-type heavily doped regions N+ are formed over the active regions OD. In some embodiments, the second portions of the active regions OD, uncovered by the gate spacers 140 and the dummy gate structures 130, may be doped with p-type dopants, such as boron; n-type dopants, such as phosphorus or arsenic; and/or other suitable dopants including combinations thereof, for example, by suitable ion plantation processes, thereby forming the p-type heavily doped region P+ and the n-type heavily doped regions N+. The n-type heavily doped regions N+ in the substrate 110 may serve as source/drain regions SD for n-type devices. The p-type heavily doped region P+ in the n-type well region NW may serve as source/drain regions SD for p-type devices. The n-type heavily doped region N+ in the n-type well region NW may serve as an n-type strap region NStrap biasing the n-type well region NW. The p-type heavily doped region P+ in the substrate 110 may serve as a p-type strap region PStrap biasing the substrate 110.

In some embodiments, the p-type heavily doped regions P+ and n-type heavily doped regions N+ are source/drain epitaxial structures formed on opposite sides of the dummy gate structures 130. The source/drain epitaxial structures may include Ge, Si, GaAs, AlGaAs, SiGe, GaAsP, SiP, or other suitable material. The source/drain epitaxial structures may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures are not in-situ doped, an implantation process (i.e., a junction implant process) is performed to dope the source/drain epitaxial structures. The source/drain epitaxial structures may be formed by performing an epitaxial growth process that provides an epitaxial material on the exposed surfaces of the active regions OD. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the active regions OD.

After the p-type heavily doped regions P+ and n-type heavily doped regions P+ (e.g., the source/drain regions SD, the n-type strap regions NStrap, and the p-type strap region PStrap) are formed, an interlayer dielectric (ILD) 160 is formed over the substrate 110 and surrounding the source/drain regions SD. The ILD 160 may include silicon oxide, oxynitride or other suitable materials. The ILD 160 includes a single layer or multiple layers. The ILD 160 can be formed by a suitable technique, such as CVD or ALD. A chemical mechanical polishing (CMP) process may be performed to remove an excess portion of the ILD 160 until reaching the dummy gate structures 130. After the chemical mechanical planarization (CMP) process, the dummy gate structures 130 are exposed from the ILD 160. In some embodiments, a contact etch stop layer (CESL) may be blanket formed over the substrate 110 prior to the formation of the ILD 160. In some examples, the CESL includes a silicon nitride layer, silicon oxide layer, a silicon oxynitride layer, and/or other suitable materials having a different etch selectivity than the ILD 160.

Reference is made to FIGS. 14A-14C. A replacement gate (RPG) process scheme is employed. The dummy gate structures 130 in the regions RA and RC are replaced with high-k/metal gate structures 170. For example, the dummy gate structures 130 (see FIGS. 13A and 13B) are removed to form a plurality of gate trenches. The dummy gate structures 130 are removed by a selective etch process, including a selective wet etch or a selective dry etch, and carries a substantially vertical profile of the gate spacers 140. The gate trenches expose portions of the active region OD. Then, the high-k/metal gate structures 170 are formed respectively in the gate trenches and cover the active region OD. The high-k/metal gate structures 170 may include a gate dielectric layer 172 and a metal-containing layer 174 over the gate dielectric layer 172.

The gate dielectric layer 172 may include an interfacial layer and a high-k dielectric layer over the interfacial layer. The interfacial layer may include silicon oxides, for example, formed by thermal oxidation process. The high-k dielectric layers, as used and described herein, include dielectric materials having a high dielectric constant, for example, greater than that of thermal silicon oxide (˜3.9). The high-k dielectric layer may include a high-k dielectric layer such as tantalum, hafnium, titanium, lanthanum, aluminum and their carbide, silicide, nitride, boride combinations. The high-k dielectric layer may be formed by ALD, PVD, CVD, oxidation, and/or other suitable methods.

The metal-containing layer 174 may include a metal, metal alloy, metal carbide, metal silicide, metal carbide silicide, metal carbide nitride, and/or metal boride. In some embodiments, the metal-containing layer 174 may include a single layer or alternatively a multi-layer structure, such as various combinations of a metal layer with a work function to enhance the device performance (work function metal layer), liner layer, wetting layer, adhesion layer and a conductive layer of metal, metal alloy or metal silicide. For example, the metal-containing layer 174 may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The work function layer(s) may be deposited by CVD, PVD, electro-plating and/or other suitable process. In some embodiments, the multi-layer metal-containing layers 174 may include the same or different materials.

In some embodiments, in the regions RB and RD, some of the dummy gate structures 130 are replaced with a suitable isolation auxiliary structures PODE, thereby breaking the active regions OD. The isolation auxiliary structures PODE may be include suitable dielectric materials. In some other embodiments, for breaking the active region OD, the dummy gate structures 130 in the regions RB and RD may be replaced with floating high-k/metal gate structures separated from the high-k/metal gate structures 170 in regions RA and RC, thereby omitting the suitable isolation auxiliary structures PODE. In some other embodiments, for breaking the active region OD, the isolation structures 120 can be arranged according to the auxiliary structures PODE in the layouts, thereby omitting the suitable isolation auxiliary structures PODE.

While the p-type strap regions PStrap of the bit BT1 and the p-type strap regions PStrap of the bit BT2 may share the same active region OD, the isolation auxiliary structures PODE may spaces the p-type strap regions PStrap of the bit BT1 from the p-type strap regions PStrap of the bit BT2. Since, the isolation auxiliary structures PODE is formed by replacing the dummy gate structures 130 with the dielectric materials, a space between the p-type strap regions PStrap of the bit BT1 and the p-type strap regions PStrap of the bit BT2 sharing the same active region OD may be less than twice a cell poly pitch CPP. The cell poly pitch CPP is the center-to-center pitch of every two adjacent dummy gate structures 130. In the context, the cell poly pitch CPP may also be referred to as a gate pitch.

Reference is made to FIGS. 15A and 15B. An ILD 180 is formed over the ILD 160 and covering the high-k/metal gate structures 170, and the contacts MD are formed over the heavily doped region P+ and N+. The ILD 180 may include silicon oxide, oxynitride or other suitable materials. The ILD 180 includes a single layer or multiple layers. The ILD 180 can be formed by a suitable technique, such as CVD or ALD.

The contacts MD may also be referred to as contact plugs. In some embodiments, the contact formation step comprises etching contact openings through the ILD 180 and the ILD 160 to expose surfaces of the heavily doped region P+ and N+, and deposits one or more metal materials to fill the contact openings. A CMP process may be performed to remove excess metal materials outside the contact openings, while leaving metal materials in the contact openings to serve as the contacts MD. The one or more metal materials may include W, Ru, Co, Cu, Ti, TiN, Ta, TaN, Mo, Ni, the like or combinations thereof. The one or more metal materials may be deposited by suitable deposition techniques (e.g., CVD, PVD, ALD, the like or combinations thereof). In some other embodiments, metal silicides may be formed between the contacts MD and the underlying heavily doped region P+ and N+ for reducing contact resistance.

An ILD 190 is formed over the contacts MD, and conductive structures VD and VDR are formed in the ILD 190 and over the contacts MD. The ILD 190 may include silicon oxide, oxynitride or other suitable materials. The ILD 190 includes a single layer or multiple layers. The ILD 190 can be formed by a suitable technique, such as CVD or ALD. In some embodiments, the formation step of the conductive structures VD and VDR comprises etching openings through the ILD 190 to expose surfaces of the contacts MD, and deposits one or more metal materials to fill the openings. A CMP process may be performed to remove excess metal materials outside the contact openings, while leaving metal materials in the openings to serve as the conductive structures VD and VDR. The one or more metal materials may include W, Ru, Co, Cu, Ti, TiN, Ta, TaN, Mo, Ni, the like or combinations thereof. The one or more metal materials may be deposited by suitable deposition techniques (e.g., CVD, PVD, ALD, the like or combinations thereof).

After the formation of the conductive structures VD and VDR, a multilayer interconnection (MLI) structure 200 is formed over the substrate 110. The MLI structure 200 may include at least three metallization layers. The number of metallization layers may vary according to design specifications of the integrated circuit structure. The metallization layers each comprise one or more inter-metal dielectric (IMD) layers, one or more horizontal interconnects respectively extending horizontally in the IMD layers, and one or more vertical interconnects respectively extending vertically in the IMD layers. For example, the metallization layer comprises IMD layers 202, horizontal interconnects (e.g., metal lines 204) and vertical interconnects (e.g., metal via 206). The metallization layers can be formed using, for example, a single damascene process, a dual damascene process, the like, or combinations thereof. In some embodiments, the IMD layers 202 may include low-k dielectric materials having k values, for example, lower than about 4.0 or even 2.0. The metal lines and vias 204 and 206 may comprise metal materials such as W, Ru, Co, Cu, Ti, TiN, Ta, TaN, Mo, Ni, combinations thereof, or the like.

The conductive structures VD are in contact with the metal lines 204 of the MLI structure 200 to make signal/power electrical connection to the source/drain regions SD. The metal lines 204 of the MLI structure 200 may include a high power rail VDD and a lower power rail VSS. The conductive structures VDR are in contact with the high power rail VDD and the lower power rail VSS to make power electrical connection from the high power rail VDD and a lower power rail VSS to the n-type strap regions NStrap and the p-type strap region PStrap, respectively. Thus, the n-type strap regions NStrap is tied to the high power rail VDD, and the p-type strap region PStrap is tied to the lower power rail VSS. In some embodiments, from the layout top view as shown in FIG. 15A, the conductive structures VDR may be an elongated rectangular shape. Pads 105 may be formed over the MLI structure 200. The pads 105 can be electrically connected to the transferring circuit TX, the receiving circuit RX, and the ESD protection circuit 104a through the metal lines and vias 204 and 206, the conductive structures VD and VG.

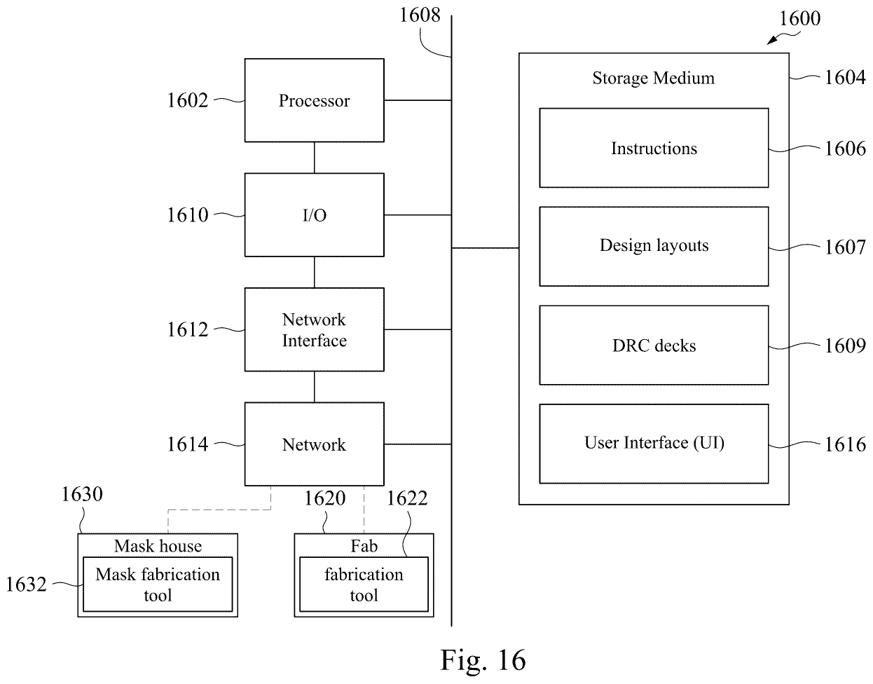

Reference is made to FIG. 16. FIG. 16 is a schematic diagram of an electronic design automation (EDA) system in accordance with some embodiments of the present disclosure. Methods described herein of generating design layouts, e.g., layouts as discussed above, in accordance with one or more embodiments, are implementable, for example, using EDA system 1600, in accordance with some embodiments. At least I/O circuit 101a, 101b, 101c, and/or 101d is manufactured by a layout design corresponding an integrated circuit. In some embodiments, EDA system 1600 is a computing device that is capable of executing one or more automatic placement & routing (APR) operations. The EDA system 1600 including a hardware processor 1602 and a non-transitory, computer-readable storage medium 1604. Computer-readable storage medium 1604, amongst other things, is encoded with, i.e., stores, a set of executable instructions 1606, design layouts 1607, design rule check (DRC) decks 1609 or any intermediate data for executing the set of instructions. Each design layout 1607 may include a graphical representation of an integrated chip, such as for example, a GSII file. Each DRC deck 1609 may include a list of design rules specific to a semiconductor process chosen for fabrication of a design layout 1607. Execution of instructions 1606, design layouts 1607 and DRC decks 1609 by hardware processor 1602 represents (at least in part) an EDA tool which implements a portion or all of, e.g., the methods described herein in accordance with one or more embodiments (hereinafter, the noted processes and/or methods).

Processor 1602 is electrically coupled to computer-readable storage medium 1604 via a bus 1608. Processor 1602 is also electrically coupled to an I/O interface 1610 by bus 1608. A network interface 1612 is also electrically connected to processor 1602 via bus 1608. Network interface 1612 is connected to a network 1614, so that processor 1602 and computer-readable storage medium 1604 are capable of connecting to external elements via network 1614. Processor 1602 is configured to execute instructions 1606 encoded in computer-readable storage medium 1604 in order to cause EDA system 1600 to be usable for performing a portion or all of the noted processes and/or methods. In one or more embodiments, processor 1602 is a central processing unit (CPU), a multi-processor, a distributed processing system, an application specific integrated circuit (ASIC), and/or a suitable processing unit.

In one or more embodiments, computer-readable storage medium 1604 is an electronic, magnetic, optical, electromagnetic, infrared, and/or a semiconductor system (or apparatus or device). For example, computer-readable storage medium 1604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1604 includes a compact disk-read only memory (CD-ROM), a compact disk-read/write (CD-R/W), and/or a digital video disc (DVD).

In one or more embodiments, computer-readable storage medium 1604 stores instructions 1606, design layouts 1607 (e.g., layouts including the I/O circuit 101a, 101b, 101c, and/or 101d as discussed previously) and DRC decks 1609 configured to cause EDA system 1600 (where such execution represents (at least in part) the EDA tool) to be usable for performing a portion or all of the noted processes and/or methods. In one or more embodiments, storage medium 1604 also stores information which facilitates performing a portion or all of the noted processes and/or methods.

EDA system 1600 includes I/O interface 1610. I/O interface 1610 is coupled to external circuitry. In one or more embodiments, I/O interface 1610 includes a keyboard, keypad, mouse, trackball, trackpad, touchscreen, and/or cursor direction keys for communicating information and commands to processor 1602.

EDA system 1600 also includes network interface 1612 coupled to processor 1602. Network interface 1612 allows EDA system 1600 to communicate with network 1614, to which one or more other computer systems are connected. Network interface 1612 includes wireless network interfaces such as BLUETOOTH, WIFI, WIMAX, GPRS, or WCDMA; or wired network interfaces such as ETHERNET, USB, or IEEE-1388. In one or more embodiments, a portion or all of noted processes and/or methods, is implemented in two or more EDA systems 1600.

EDA system 1600 is configured to receive information through I/O interface 1610. The information received through I/O interface 1610 includes one or more of instructions, data, design rules, libraries of standard cells, and/or other parameters for processing by processor 1602. The information is transferred to processor 1602 via bus 1608. EDA system 1600 is configured to receive information related to a user interface (UI) 1616 through I/O interface 1610. The information is stored in computer-readable medium 1604 as UI 1616.

Also illustrated in FIG. 16 are fabrication tools associated with the EDA system 1600. For example, a mask house 1630 receives a design layout from the EDA system 1600 by, for example, the network 1614, and the mask house 1630 has a mask fabrication tool 1632 (e.g., a mask writer) for fabricating one or more photomasks (e.g., photomasks used for fabricating I/O circuit 101a, 101b, 101c, and/or 101d as discussed above) based on the design layout generated from the EDA system 1600. An IC fabricator (“Fab”) 1620 may be connected to the mask house 1630 and the EDA system 1600 by, for example, the network 1614. Fab 1620 includes an IC fabrication tool 1622 for fabricating IC chips (e.g., layouts including the I/O circuit 101a, 101b, 101c, and/or 101d as discussed above) using the photomasks fabricated by the mask house 1630. By way of example and not limitation, the IC fabrication tool 1622 includes one or more cluster tools for fabricating IC chips. The cluster tool may be a multiple reaction chamber type composite equipment which includes a polyhedral transfer chamber with a wafer handling robot inserted at the center thereof, a plurality of process chambers (e.g., CVD chamber, PVD chamber, etching chamber, annealing chamber or the like) positioned at each wall face of the polyhedral transfer chamber; and a loadlock chamber installed at a different wall face of the transfer chamber.

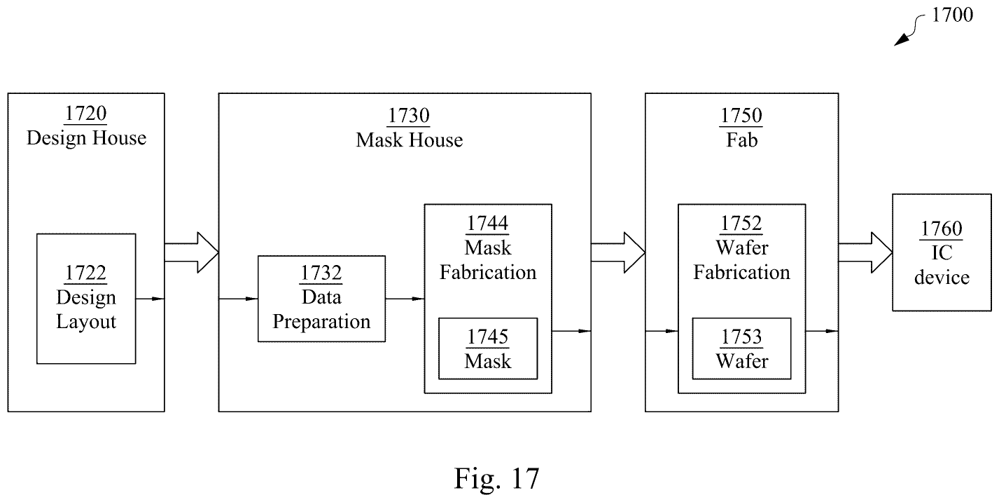

Reference is made to FIG. 17. FIG. 17 is a block diagram of an IC manufacturing system and an IC manufacturing flow associated therewith, in accordance with some embodiments of the present disclosure. In some embodiments, based on one or more design layouts, e.g., layouts including the I/O circuit 101a, 101b, 101c, and/or 101d as discussed above, one or more photomasks and one or more integrated circuits are fabricated using manufacturing system 1700.

In FIG. 17, an IC manufacturing system 1700 includes entities, such as a design house 1720, a mask house 1730, and a Fab 1750, that interact with one another in the design, development, and manufacturing cycles and/or services related to manufacturing ICs 1760. The entities in IC manufacturing system 1700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1720, mask house 1730, and Fab 1750 is owned by a single larger company. In some embodiments, two or more of design house 1720, mask house 1730, and Fab 1750 coexist in a common facility and use common resources.

Design house (or design team) 1720 generates design layouts 1722 (e.g., layouts including the I/O circuit 101a, 101b, 101c, and/or 101d as discussed above). Design layouts 1722 include various geometrical patterns designed for ICs 1760 (e.g., I/O circuit 101a, 101b, 101c, and/or 101d with resistor circuits as discussed above). The geometrical patterns correspond to patterns of metal, oxide, or semiconductor layers that make up the various components of ICs 1760 to be fabricated. The various layers combine to form various device features. For example, a portion of design layout 1722 includes various circuit features, such as active regions, passive regions, functional gate structures, resistor structures, gate contacts, resistor contacts, source/drain contacts, and/or metal lines, to be formed on a semiconductor wafer. Design house 1720 implements a proper design procedure to form design layout 1722. The design procedure includes one or more of logic design, physical design or place and route. Design layout 1722 is presented in one or more data files having information of the geometrical patterns and a netlist of various nets. For example, design layout 1722 can be expressed in a GDSII file format or DFII file format.

Mask house 1730 includes data preparation 1732 and mask fabrication 1744. Mask house 1730 uses design layout 1722 (e.g., layout including the I/O circuit 101a, 101b, 101c, and/or 101d as discussed above) to manufacture one or more photomasks 1745 to be used for fabricating the various layers of IC 1760 according to design layout 1722. Mask house 1730 performs mask data preparation 1732, where design layout 1722 is translated into a representative data file (“RDF”). Mask data preparation 1732 provides the RDF to mask fabrication 1744. Mask fabrication 1744 includes a mask writer. A mask writer converts the RDF to an image on a substrate, such as a photomask (reticle) 1745. Design layout 1722 is manipulated by mask data preparation 1732 to comply with particular characteristics of the mask writer and/or rules of fab 1750. In FIG. 17, mask data preparation 1732 and mask fabrication 1744 are illustrated as separate elements. In some embodiments, mask data preparation 1732 and mask fabrication 1744 can be collectively referred to as mask data preparation.

In some embodiments, mask data preparation 1732 includes optical proximity correction (OPC) which uses lithography enhancement techniques to compensate for image errors, such as those that can arise from diffraction, interference, other process effects and the like. OPC adjusts design layout 1722. In some embodiments, mask data preparation 1732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1732 includes a mask rule checker (MRC) that checks design layout 1722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies design layout 1722 diagram to compensate for limitations during mask fabrication 1744, which may undo part of the modifications performed by OPC in order to meet mask creation rules.

In some embodiments, mask data preparation 1732 includes lithography process checking (LPC) that simulates processing that will be implemented by Fab 1750 to fabricate ICs 1760. LPC simulates this processing based on design layout 1722 to create a simulated manufactured integrated circuit, such as IC 1760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine design layout 1722.

After mask data preparation 1732 and during mask fabrication 1744, a photomask 1745 or a group of photomasks 1745 are fabricated based on the design layout 1722. In some embodiments, mask fabrication 1744 includes performing one or more lithographic exposures based on the design layout 1722. In some embodiments, an electron-beam (e-beam) or a mechanism of multiple e-beams is used to form a pattern on a photomask 1745 based on design layout 1722. Photomask 1745 can be formed in various technologies. In some embodiments, photomask 1745 is formed using binary technology. In some embodiments, a mask pattern includes opaque regions and transparent regions. A radiation beam, such as an ultraviolet (UV) beam, used to expose the radiation sensitive material layer (e.g., photoresist) which has been coated on a wafer, is blocked by the opaque regions and transmits through the transparent regions. In one example, a binary mask version of photomask 1745 includes a transparent substrate (e.g., fused quartz) and an opaque material (e.g., chromium) coated in the opaque regions of the binary mask. In another example, photomask 1745 is formed using a phase shift technology. In a phase shift mask (PSM) version of photomask 1745, various features in the pattern formed on the phase shift photomask are configured to have proper phase difference to enhance the resolution and imaging quality. In various examples, the phase shift photomask can be attenuated PSM or alternating PSM. The photomask(s) generated by mask fabrication 1744 is used in a variety of processes. For example, such a mask(s) is used in an ion implantation process to form various doped regions in semiconductor wafer 1753, in an etching process to form various etching regions in semiconductor wafer 1753, and/or in other suitable processes.

Fab 1750 may include wafer fabrication 1752. Fab 1750 is an IC fabrication business that includes one or more manufacturing facilities for the fabrication of a variety of different IC products. In some embodiments, Fab 1750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (BEOL fabrication), and a third manufacturing facility may provide other services for the foundry business.

Fab 1750 uses photomask(s) 1745 fabricated by mask house 1730 to fabricate ICs 1760. Thus, fab 1750 at least indirectly uses design layout(s) 1722 (e.g., layouts including the I/O circuit 101a, 101b, 101c, and/or 101d as discussed above) to fabricate ICs 1760. In some embodiments, wafer 1753 is processed by fab 1750 using photomask(s) 1745 to form ICs 1760. In some embodiments, the device fabrication includes performing one or more photolithographic exposures based at least indirectly on design layout 1722.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. One advantage is that by sharing the common parts with each other, two bits respectively including I/O circuits are merged into a multi-bit cell structure, thereby obviously reducing the redundant parts and improve the chip utilization. Another advantage is that the form factor of the multi-bit cell structure cost less cell poly pitch, thereby occupying less area than the areas of the single bits. Still another advantage is that the multi-bit cell can satisfy a number of fins of ESC protection circuit according to the design rule check (DRC) with reduced regions for the I/O circuits.

In some embodiments of the present disclosure, an integrated circuit device includes a semiconductor substrate, a plurality of multi-bit cells over the semiconductor substrate, a first pad, and a second pad. Each of the multi-bit cells includes a first bit and a second bit. The first bit includes a first electrostatic discharge (ESD) protection circuit and a first strap region in the semiconductor substrate. The second bit includes a second ESD protection circuit and a second strap region in the semiconductor substrate. The first strap region of the first bit is symmetric to the second strap region of the second bit with respect to a border between the first bit and the second bit in a top view, and the first p-type strap region of the first bit and the second strap region of the second bit have a first conductivity type. The first pad is connected to the first ESD protection circuit. The second pad is connected to the second ESD protection circuit.

In some embodiments of the present disclosure, an integrated circuit device includes a semiconductor substrate, a plurality of multi-bit cells over the semiconductor substrate, a first pad, and a second pad. Each of the multi-bit cells includes a first bit and a second bit. The first bit includes a first ESD protection circuit. The second bit includes a second ESD protection circuit. The first ESD protection circuit of the first bit is substantially symmetric to the second ESD protection circuit of the second bit with respect to a border between the first bit and the second bit in a top view. The first pad is connected to the first ESD protection circuit. The second pad is connected to the second ESD protection circuit.

In some embodiments of the present disclosure, a method for manufacturing an integrated circuit device is provided. The method includes forming a first n-type device and a first p-type device in a first region of a semiconductor substrate and forming a second n-type device and a second p-type device in a second region of the semiconductor substrate, wherein the first n-type device and the first p-type device are substantially symmetric to the second n-type device and the second p-type device with respect to a border between the first region and the second region in a top view; forming an interconnect structure over the first n-type device, the first p-type device, the second n-type device, and the second p-type device, such that the first n-type device and the first p-type device forms a first ESD protection circuit, and the second n-type device and the second p-type device forms a second ESD protection circuit; forming a first pad over the interconnect structure and electrically connected to the first n-type device and the first p-type device of the first ESD protection circuit; and forming a second pad over the interconnect structure and electrically connected to the second n-type device and the second p-type device of the second ESD protection circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a semiconductor substrate;
a plurality of multi-bit cells over the semiconductor substrate, each of the multi-bit cells comprising:
a first bit, comprising a first electrostatic discharge (ESD) protection circuit and a first strap region in the semiconductor substrate; and
a second bit, comprising a second ESD protection circuit and a second strap region in the semiconductor substrate, wherein the first strap region of the first bit is substantially symmetric to the second strap region of the second bit with respect to a border between the first bit and the second bit in a top view, and the first strap region of the first bit and the second strap region of the second bit have a first conductivity type;
a first pad connected to the first ESD protection circuit; and
a second pad connected to the second ESD protection circuit.

2. The integrated circuit device of claim 1, wherein an n-type device of the first ESD protection circuit of the first bit is symmetric to an n-type device of the second ESD protection circuit of the second bit with respect to the border between the first bit and the second bit in the top view.

3. The integrated circuit device of claim 1, wherein a p-type device of the first ESD protection circuit of the first bit is symmetric to a p-type device of the second ESD protection circuit of the second bit with respect to the border between the first bit and the second bit in the top view.

4. The integrated circuit device of claim 1, further comprising:
a power rail connected to the first strap region and the second strap region.

5. The integrated circuit device of claim 1, wherein the semiconductor substrate has at least one well region having a second conductivity type opposite to the first conductivity type, and the first strap region and the second strap region are spaced apart from the at least one well region.

6. The integrated circuit device of claim 5, wherein the at least one well region does not extend across the border between the first bit and the second bit in the top view.

7. The integrated circuit device of claim 5, wherein the first bit further comprises a third strap region in a first one of a plurality of the well regions, the second bit further comprises a fourth strap region in a second one of the well regions spaced apart from the first one of the well regions, and the third strap region and the fourth strap region have the second conductivity type.

8. The integrated circuit device of claim 1, wherein a space between the first strap region of the first bit and the second strap region of the second bit is less than twice a gate pitch of the first ESD protection circuit.

9. The integrated circuit device of claim 1, wherein the first conductivity type corresponds to a p-type conductivity.

10. An integrated circuit device, comprising:
a semiconductor substrate;
a plurality of multi-bit cells over the semiconductor substrate, each of the multi-bit cells comprising:
a first bit, comprising a first ESD protection circuit; and
a second bit, comprising a second ESD protection circuit, wherein the first ESD protection circuit of the first bit is substantially symmetric to the second ESD protection circuit of the second bit with respect to a border between the first bit and the second bit in a top view;
a first pad connected to the first ESD protection circuit; and
a second pad connected to the second ESD protection circuit.

11. The integrated circuit device of claim 10, wherein an n-type device of the first ESD protection circuit adjoins an n-type device of the second ESD protection circuit in the top view.

12. The integrated circuit device of claim 10, wherein a space between an n-type device of the first ESD protection circuit and an n-type device of the second ESD protection circuit is less than twice a gate pitch of the first ESD protection circuit.

13. The integrated circuit device of claim 10, wherein an n-type device of the first ESD protection circuit and an n-type device of the second ESD protection circuit are spaced apart from each other by a first space, and a p-type device of the first ESD protection circuit and a p-type device of the second ESD protection circuit are spaced apart from each other by a second space greater than the first space.

14. The integrated circuit device of claim 10, wherein an n-type device of the first ESD protection circuit is over a first active region of the semiconductor substrate, the first bit further comprises an n-type strap region over a second active region of the semiconductor substrate, and the second active region is aligned with the first active region.

15. The integrated circuit device of claim 10, wherein a length of each of the multi-bit cells measured along a direction substantially perpendicular to an extension direction of the border is greater than a length of each of the multi-bit cells measured along a direction substantially parallel to the extension direction of the border.

16. The integrated circuit device of claim 10, wherein the first bit further comprises a first transferring circuit and a first receiving circuit, the second bit further comprises a second transferring circuit and a second receiving circuit, wherein the first transferring circuit of the first bit is substantially symmetric to the second transferring circuit of the second bit with respect to the border between the first bit and the second bit in the top view, and the first receiving circuit of the first bit is substantially symmetric to the second receiving circuit of the second bit with respect to the border between the first bit and the second bit in the top view.

17. A method for manufacturing an integrated circuit device, comprising:
forming a first n-type device and a first p-type device in a first region of a semiconductor substrate and forming a second n-type device and a second p-type device in a second region of the semiconductor substrate, wherein the first n-type device and the first p-type device are substantially symmetric to the second n-type device and the second p-type device with respect to a border between the first region and the second region in a top view;
forming an interconnect structure over the first n-type device, the first p-type device, the second n-type device, and the second p-type device, such that the first n-type device and the first p-type device forms a first ESD protection circuit, and the second n-type device and the second p-type device forms a second ESD protection circuit;
forming a first pad over the interconnect structure and electrically connected to the first n-type device and the first p-type device of the first ESD protection circuit; and
forming a second pad over the interconnect structure and electrically connected to the second n-type device and the second p-type device of the second ESD protection circuit.

18. The method of claim 17, further comprising:
forming a first p-type strap region in the first region of the semiconductor substrate; and
forming a second p-type strap region in the second region of the semiconductor substrate, wherein the first p-type strap region is substantially symmetric to the second p-type strap region with respect to the border between the first region and the second region in the top view.

19. The method of claim 18, wherein the first p-type strap region adjoins the second p-type strap region.

20. The method of claim 17, further comprising:
forming a first n-type strap region in the first region of the semiconductor substrate; and
forming a second n-type strap region in the second region of the semiconductor substrate, wherein the first n-type strap region is substantially symmetric to the second n-type strap region with respect to the border between the first region and the second region in the top view.
